(19) United States
(12) Patent Application Publication
(10) Pub. No.: US 2024/0044044 A1
(43) Pub. Date: Feb. 8, 2024

(54) CRYSTAL GROWTH DEVICE AND METHOD FOR GROWING A SEMICONDUCTOR

(71) Applicant: Forschungsverbund Berlin e.V., Berlin (DE)

(72) Inventors: Carsten HARTMANN, Berlin (DE); Thomas STRAUBINGER, Berlin (DE)

(21) Appl. No.: 18/363,366

(22) Filed: Aug. 1, 2023

(30) Foreign Application Priority Data
Aug. 2, 2022 (DE) 102022119343.8

(51) Int. Cl. C30B 29/36; C30B 29/40; C30B 23/00

(52) U.S. Cl. CPC C30B 29/36; C30B 29/403; C30B 23/002

(57) ABSTRACT

The invention relates to a crystal growth device for growing a semiconductor from a gas phase, the crystal growth device comprising, a crucible, a heater, and a holding plate. The crucible on a crucible vessel and a crucible lid supported on the crucible vessel, wherein the crucible vessel is configured to receive and hold a source material for the semiconductor during growth of the semiconductor. The heater is configured and arranged to heat the source material in the crucible vessel so that the source material at least partially changes to its gaseous phase and flows toward the crucible lid. The holding plate is configured to hold a seed crystal on a side of the holding plate facing the crucible lid, and to allow deposition of the source material that has changed into its gas phase on the seed crystal for growing the semiconductor. The holding plate is further configured to be spaced from a crucible bottom of the crucible vessel for growing the semiconductor, such that it is located between the source material and the crucible lid.

### CROSS-REFERENCE TO RELATED APPLICATION

This application claims the benefit of German Patent Application No. 102022119343.8 filed on Aug. 2, 2022, the contents of which are incorporated herein by reference in its entirety.

### FIELD OF THE INVENTION

The invention relates to a crystal growth device and a method for growing a semiconductor from a gas phase. The invention further relates to a semiconductor, in particular comprising AlN or SiC. The invention further relates to a use of a semiconductor for fabricating a semiconductor substrate and to a semiconductor substrate, in particular comprising AlN or SiC.

### BACKGROUND OF THE INVENTION

Semiconductor substrates made of aluminum nitride (AlN) or silicon carbide (SiC) are required for the manufacture of electronic and opto-electronic devices in the semiconductor industry. SiC, for example, is widely used in power electronics, e.g., for the production of Schottky diodes and metal-oxide-semiconductor field-effect transistors (MOSFET). AlN is used for the production of light-emitting diodes (LEDs), laser diodes, for high-frequency applications and also in power electronics. AlN is particularly suitable for the production of UV-C LEDs, which can be used for disinfection applications but also in medical diagnostics and for detecting biological agents. For the production of such electronic or opto-electronic devices, substrates of AlN and SiC with high crystal quality, i.e., low dislocation densities, and comparatively large diameters of, for example, two inches and more are required in particular.

Both, AlN and SiC semiconductor substrates with high crystal quality can be fabricated from corresponding AlN or SiC semiconductor bulk crystals grown from the gas phase by high temperature crystal growth techniques. For example, such AlN or SiC semiconductor bulk crystals can be fabricated by physical vapor transport (PVT).

In the context of fabricating an AlN or SiC semiconductor by physical vapor phase transport, a source material is typically heated in a crucible so that it partially sublimates. The sublimated source material flows toward a crucible lid of the crucible due to a corresponding temperature gradient within the crucible. A seed holder is attached to the crucible lid, which holds a seed crystal. The sublimated source material then flows toward the seed crystal and desublimates at the seed crystal, so that the AlN or SiC semiconductor grows at the seed crystal.

For example, the scientific publications “Preparation of Bulk AlN Seeds by Spontaneous Nucleation of Freestanding Crystals”, Japanese Journal of applied Physics, 52,08JA06, 2013” by C. Hartmann et al. and “Preparation of deep UV transparent AlN substrates with high structural perfection for optoelectronic devices”, Cryst Eng Comm, 18, 3488, 2016 by C. Hartmann et al. described the fabrication of AlN semiconductors by physical gas phase transport, where the seed crystal is held on a crucible lid and placed facing the source material. Also in WO 2021/030394 A1 the fabrication of AlN semiconductors by physical vapor phase transport is described, where in the process described therein, a thermal shield is used to enhance a radial thermal gradient within the crystal growth chamber.

However, there is still an ever-increasing demand for substrates especially of AlN and SiC with further improved crystal quality and thereby comparatively large diameters, especially of two inches or more.

### SUMMARY OF THE INVENTION

Therefore, the present invention is based on the objective of providing a crystal growth device and a method which enable semiconductors, in particular of AlN and SiC, to be fabricated with a comparatively large diameter and, at the same time, a comparatively high crystal quality. Furthermore, the present invention is based on the objective to provide a semiconductor, in particular of AlN and SiC, from which a semiconductor substrate with a comparatively large diameter and a comparatively high crystal quality can be fabricated. Furthermore, a corresponding semiconductor substrate shall be provided.

According to the invention, a crystal growth device for growing a semiconductor from a gas phase is proposed, comprising a crucible, a heater, and a holding plate. The crucible has a crucible vessel and a crucible lid configured to cover the crucible vessel. The crucible vessel is configured to receive and hold a source material for the semiconductor during growth of the semiconductor. The heater is configured and arranged to heat the source material in the crucible vessel so that the source material at least partially changes to its gaseous phase and flows toward the crucible cover. The holding plate is configured to hold a seed crystal on a side of the holding plate facing the crucible lid, and to allow deposition of the source material that has changed into its gas phase on the seed crystal for growing the semiconductor. The holding plate is further configured to be spaced from a crucible bottom of the crucible vessel for growing the semiconductor such that it is located between the source material and the crucible lid, particularly prior to heating the source material.

Spaced from the crucible bottom means in particular that for growing the semiconductor, the distance between the surface of the holding plate facing the crucible bottom and the crucible bottom is more than 0 mm. Due to the fact that the holding plate is arranged at a distance from a crucible bottom of the crucible vessel, source material can be arranged between the holding plate and the crucible bottom. In particular, the entire crucible bottom may be covered with source material. Accordingly, when growing the semiconductor, the holding plate is not in direct contact with the crucible bottom. For growing the semiconductor, the holding plate is arranged above the source material so that source material is located between the crucible bottom and the holding plate.

The holding plate serves several functions in the crystal growth device. First, the holding plate serves to hold a seed crystal. The seed crystal is arranged on the surface of the holding plate facing the crucible lid. The seed crystal is then located between the holding plate and the crucible lid. The holding plate further serves to regulate the amount of sublimated source material flowing past the seed crystal toward the crucible lid during growth of the semiconductor. In addition, the holding plate serves to specify the location at which sublimated source material flows past the holding plate or through a free surface of the holding plate toward the crucible lid. The holding plate can thus be used to selectively control and adjust the growth of the semiconductor to be grown.

The invention includes the recognition that the crystal quality of a Wurtzite crystal such as AlN or SiC, and in particular the dislocations, is typically inherited in the c-direction, so that seed crystals or seed wafers with a diameter of at least two inches and good crystal quality are regularly required for the fabrication of high-quality AlN or SiC substrates. However, the increase in diameter of a seed crystal is often comparatively small in known crystal growth processes, so that typically multiple crystal growth iterations are required to obtain large diameter seed crystals or seed wafers. As a result, the probability of local defect cluster formation is comparatively high, especially since crystal growth typically occurs at high growth rates or low temperature on the c-plane, which is usually unfavorable. In addition, defect formation is favored by thermal stresses that arise due to the different thermal expansion properties of commonly used seed holders and the attached seed crystal during heating and cooling.

The invention is based on the considerations that the disadvantages of known crystal growth methods can be eliminated or at least reduced if the seed crystal is not arranged opposite the source material on the crucible lid of the crucible, i.e. has a free line of sight to the source material, but instead, is arranged on a holding plate so that the seed crystal faces the crucible lid and no longer the source material, i.e., no longer has a free line of sight to the source material. This allows the semiconductor to grow in the direction of the crucible lid and not in the direction of the hot source material as in conventional processes. In the fabrication of an AlN semiconductor, supersaturation and a growth rate on the N-polar c-plane can thus be reduced and comparatively faster lateral growth, i.e., growth on the m-surface, can be enabled. Accordingly, lateral growth of a SiC semiconductor can also be favored. On the one hand, this has the advantage that a target diameter of the semiconductor can be achieved comparatively faster, for example with fewer iterations. On the other hand, this has the advantage that the semiconductor can be fabricated comparatively more defect-free, since structural defects are typically inherited in the c-direction, but not in the m-direction. As a result, a dislocation density in a crystal volume grown on an m-surface can be significantly lower than in the original seed crystal.

The arrangement of the seed crystal on the holding plate has the further advantage that a growth temperature on a side of the seed crystal facing the crucible lid can be comparatively increased, which can lead to better surface mobility and a lower tendency to defect formation. In the case of a seed crystal with Wurtzite crystal structure, e.g., made of AlN or SiC, the surface facing the crucible lid is in particular the c-surface.

Another advantage of arranging the seed crystal on the holding plate is that the seed crystal does not need to be attached to a seed holder, as is the case with conventional methods. Instead, the seed crystal can be arranged loosely on the holding plate. As a result, no thermal stresses occur due to different coefficients of thermal expansion of the seed holder and the seed crystal, as is often the case in known crystal growth processes. The semiconductor can then be fabricated with improved crystal quality, since comparatively fewer dislocations form in the semiconductor during heating and cooling.

Due to the fact that the holding plate for growing the semiconductor can be arranged at a distance from the crucible bottom of the crucible vessel so that it is located between the source material and the crucible lid, a comparatively larger amount of source material can be present in the crucible vessel. This has the advantage that, by heating the source material, a comparatively high gas flow in the direction of the crucible lid can correspondingly also be achieved. Accordingly, due to the higher material supply, comparatively high deposition rates and thus faster growth of the semiconductor can be realized, especially on the m-surfaces along which the gas species flow.

The use of a holding plate has the further advantage that the source material can have a comparatively high source temperature when growing the semiconductor. At a high source temperature, comparatively more source material sublimates, so that a comparatively large amount of gaseous source material would flow toward the crucible lid. This may also be considered detrimental, since a relatively large amount of polycrystalline material may accumulate on the crucible lid in a short time. However, with the holding plate, the amount of gaseous source material flowing toward the crucible lid can be controlled and, in particular, reduced. This can be achieved with the holding plate in that the holding plate is arranged between the source material and the crucible lid, and thus partially shields gaseous source material flowing towards the crucible lid. The holding plate thus reduces the available evaporation area of the source material. In particular, the holding plate can be used to ensure that gaseous source material can only flow in the direction of the crucible lid at predetermined positions or areas. The holding plate thus enables a comparatively high source temperature and a locally defined controlled supply of a comparatively high quantity of source material.

The arrangement of the seed crystal on the holding plate leads to the further advantage that impurities from the source material, such as oxygen, carbon or silicon, do not have direct access to the surface of the seed crystal facing the crucible lid, i.e., for example, to the c-surface in the case of a seed crystal with Wurtzite crystal structure. Since the incorporation of impurities from the source material in the lateral direction of the seed crystal, e.g., in the m-direction in the case of a Wurtzite crystal structure, is typically comparatively lower, the crystal quality of the semiconductor can be further improved by arranging the seed crystal on the holding plate. In particular, in a fabrication of an AlN semiconductor, it can be achieved that due to the comparatively reduced incorporation of impurities, absorption at low wavelengths, e.g. from 230 nm to 265 nm, which are relevant for disinfection applications, is comparatively lower.

The crystal growth device according to the invention can thus be used to fabricate semiconductors with a comparatively large diameter, high crystal quality and correspondingly low dislocation density, especially in the regions adjacent to the original seed crystal. In several iterations, the diameter of the semiconductor can be further increased to a target diameter, although comparatively fewer iterations can usually be required for this purpose. A semiconductor substrate can be fabricated directly from the semiconductor. Alternatively, a seed wafer may be fabricated from the semiconductor and used in a further crystal growth process to fabricate a semiconductor substrate. The further crystal growth process may also be carried out using the crystal growth device according to the invention, and accordingly the seed wafer may be arranged on the holding plate. However, since high growth on the c surface is often preferred for fabricating the semiconductor substrate, an alternative crystal growth method, e.g., according to the conventional physical gas phase transport explained at the beginning, might be preferred. The semiconductor substrate may also be fabricated with homogeneous doping. Since it is possible to achieve a comparatively rapid increase in the semiconductor diameter and a high crystal quality with the crystal growth device, one or more substrates can be fabricated from the semiconductor which also have a high crystal quality and, in particular, a comparatively homogeneous lattice constant within the substrate volume.

In particular, the holding plate of the crystal growth device is formed separately from the crucible and can be removed from the crucible, e.g., to introduce the source material into the crucible vessel. For growing the semiconductor, the holding plate can be spaced from a crucible bottom of the crucible vessel such that the seed crystal can be placed thereon. During fabrication, the holding plate is located in particular between the still solid source material and the crucible lid. During the growth of the semiconductor, the source material which has changed into its gaseous phase flows onto the side of the holding plate facing away from the source material in the direction of the crucible lid, so that the gaseous source material can desublimate on the seed crystal.

Accordingly, the crystal growth device may be further configured such that the at least one holding plate is formed separately from the crucible, and may be removed from the crucible for introduction of the source material and placed between the source material and the crucible lid for growth of the semiconductor. Thus, the holding plate is formed separately to the crucible.

Preferably, the holding plate for growing the semiconductor can be arranged at a distance from the crucible bottom of the crucible vessel which is from 10 mm to 100 mm, in particular from 20 mm to 80 mm, preferably from 30 mm to 60 mm. A distance of at least 10 mm is preferred so that sufficient source material can be arranged below the holding plate. A distance of 100 mm can be advantageous, since at a distance of 100 mm just enough source material can still be arranged below the holding plate so that the material flow of the gaseous source material in the direction of the crucible lid is not yet too high. However, it may also be advantageous under certain circumstances if the crucible vessel is filled with more source material, i.e., beyond a filling level of 100 mm, so that the holding plate can be arranged at a distance of, for example, 150 mm or more or 200 mm or more from the crucible bottom for growing the semiconductor between the crucible bottom and the crucible lid.

Preferably, the crystal growth device is configured in such a way that the holding plate for growing the semiconductor can be arranged at a distance from the crucible lid which is at least 10 mm, in particular at least 30 mm, preferably at least 50 mm. This can ensure that the semiconductor does not contact the crucible lid until it reaches a typical target diameter. Also, it can be prevented that the seed crystal comes into contact with amorphous or polycrystalline semiconductor material that may form on the crucible lid due to the gas flow of the gaseous source material in the direction of the crucible lid.

The holding plate can be formed in one piece. Alternatively, the holding plate can be a multi-part holding plate consisting of several holding plate parts. The multiple holding plate parts can then be arranged between the source material and the crucible lid for growing the semiconductor. A seed crystal may be arranged on one or more of the holding plate parts for growing the semiconductor.

The holding plate may be configured to be positioned at a distance above the source material in the crucible for growing the semiconductor. Alternatively, the holding plate may be configured to be placed directly on the source material in the crucible for growing the semiconductor. In this case, the holding plate thus is arranged on the source material and is in direct contact with it.

Preferably, the holding plate is configured in such a way that it does not cover, i.e., leaves free, a portion of between 5% and 75%, in particular between 10% and 60%, preferably between 30% and 50%, of the surface of the source material during growth of the semiconductor. The surface area of the closed areas of the holding plate is in particular 95% to 25%, in particular between 90% and 40%, preferably between 70% and 50% of the surface area of a cross-sectional area of the crucible vessel, for example at the level of the holding plate arranged in the crucible. This preferably applies both in the case where the holding plate is arranged at a distance from the source material and in the case where the holding plate is arranged at a distance above the source material. For the case where the holding plate is arranged at a distance from the source material, the area of the free surface of the source material can be determined by projecting holding plate geometry onto the surface of the source material. In the case of straight inner side walls of the crucible, the area of the surface of the source material corresponds in particular to the area of the cross-sectional surface of the crucible vessel.

A holding plate that does not cover a portion of 5% to 75%, in particular between 10% and 60%, preferably between 30% and 50% of the surface of the source material when growing the semiconductor may be a single-part or a multi-part holding plate. In order that a portion of 5% to 75%, in particular between 10% and 60%, preferably between 30% and 50% of the surface of the source material is not covered during growth of the semiconductor, the holding plate may have at least one feedthrough and/or have a smaller outer diameter than the inner diameter of the crucible vessel, and/or consist of a plurality of holding plate parts which are formed in such a way that free spaces are created between the plurality of holding plate parts when they are arranged on the source material.

It may be advantageous if the holding plate has at least one feedthrough which, when the holding plate is arranged between the source material and the crucible lid, extends from the surface of the holding plate facing the source material to the surface of the holding plate facing away from the crucible bottom, so that the source material which has changed into its gaseous phase can pass through the at least one feedthrough. If the holding plate is a multi-part holding plate, at least one of the plurality of holding plate parts may have at least one feedthrough.

At least one feedthrough in the holding plate is particularly advantageous if the holding plate extends over the entire inner diameter when the semiconductor is grown, i.e., completely covers the source material. However, at least one feedthrough in the holding plate may also be advantageous to provide a gas flow at a specific location of the holding plate, e.g., near a location where a seed crystal is to be placed. The feedthroughs allow gaseous source material to flow toward the crucible lid so that the gaseous source material can desublimate at the seed crystal. By way of example, the holding plate may be formed such that the seed crystal can be positioned in the center thereof. Around the center, a plurality of feedthroughs may extend through the holding plate so that the gaseous material can flow past the seed crystal toward the crucible lid and desublimate at the seed crystal along the way. However, the feedthroughs may also be arranged in a disorderly manner across the holding plate.

The feedthroughs may also be arranged in such a way that there are several predetermined locations on the holding plate at each of which a seed crystal can be arranged. A number of feedthroughs may then be arranged around each of these locations in order to guide the gaseous source material to the respective seed crystal. In the case of comparatively thicker holding plates, it may be useful if the feedthroughs lead obliquely through the holding plate in order to change the direction of flow of the gaseous source material and to guide it in the direction of a seed crystal arranged on the holding plate. Preferably, the feedthroughs are arranged such that a mass flow at the edge of a seed crystal arranged on the holding plate is comparatively homogeneous. This can be achieved, in particular, by a homogeneous arrangement of the feedthroughs around a location on the holding plate at which the respective seed crystal is to be arranged.

Preferably, the at least one feedthrough makes up a proportion of between 5% and 75%, in particular between 10% and 60%, preferably between 30% and 50%, of the holding plate. The proportion of the at least one feedthrough on the holding plate corresponds to the free area of the holding plate. The remaining part of the holding plate is closed, so that a gas flow is essentially only possible through the free area, i.e. through the feedthroughs. Further, the gaseous source material may generally also flow past the holding plate towards the crucible lid.

Preferably, the holding plate with feedthroughs is configured in such a way that it does not cover, i.e. leaves free, a portion of between 5% and 75%, in particular between 10% and 60%, preferably between 30% and 50%, of the surface of the source material during growth of the semiconductor. If the holding plate with feedthroughs has an outer diameter that is smaller than the inner diameter of the crucible vessel, the areas of the source material that are outside the holding plate are also not covered. The free portion of the surface of the source material in this case thus results from the surface area of the at least one feedthrough and the surface area of those areas which are located outside the holding plate.

However, the amount of source material flowing past the holding plate toward the crucible lid can be reduced by having a diameter of the holding plate substantially equal to or even greater than the inner diameter of the crucible.

When a diameter of the holding plate is substantially equal to the inner diameter of the crucible, the holding plate for growing a semiconductor can be arranged directly on the source material, for example. When a diameter of the holding plate is larger than the inner diameter of the crucible, the holding plate for growing a semiconductor can be arranged, for example, on a crucible rim of the crucible vessel of the crucible.

A holding plate with feedthroughs can be appropriately configured to be placed directly on the source material, i.e., in direct contact with the source material, for growing the semiconductor. The source material is preferably formed such that it sublimates by heating by means of the heater and the gaseous source material flows through the feedthroughs in the direction of the crucible lid and can desublimate at the seed crystal. However, a holding plate having feedthroughs may also be formed to have an outer diameter substantially equal to or larger than the outer diameter of the crucible vessel so that the holding plate can be placed on a crucible rim of the crucible vessel for growing the semiconductor.

The crystal growth device may be further configured such that the holding plate is formed with feedthroughs so that it can be placed on a crucible rim of the crucible vessel. The crucible lid is then preferably formed so that it can be arranged on the holding plate, in particular so that the crucible lid can cover or enclose a seed crystal arranged on the holding plate. The holding plate is then preferably located between the crucible vessel and the crucible lid for growing the semiconductor. A holding plate that can be placed on the crucible rim of the crucible vessel is particularly advantageous if the crucible is made of a material that is difficult to machine, such as tungsten (W) or tantalum carbide (TaC). Due to the comparatively high weight of W or TaC, it may be sufficient if the holding plate is placed on the crucible rim of the crucible vessel and the crucible lid is arranged on the holding plate without the need for further seals for growing the semiconductor. In this further embodiment, the holding plate preferably has an outer diameter substantially identical to or larger than the outer diameter of the crucible vessel so that the holding plate can be stably placed on the crucible rim of the crucible vessel. A holding plate that can be arranged on the crucible rim of the crucible vessel is preferably formed in a single piece.

Additionally, or alternatively, the crucible vessel may have at least one projection in a side wall of the crucible, e.g., an edge extending on the inner wall, which is formed such that the holding plate can be arranged on the at least one projection in the crucible vessel. A holding plate that can be arranged on one or more protrusions is preferably in one piece. A protrusion on a crucible sidewall can be implemented, for example, in a crucible vessel made of graphite, which is particularly suitable for the production of SiC semiconductors. It may also be possible for a first holding plate to be arranged on a protrusion in the crucible sidewall and a second holding plate to be arranged on the crucible rim of the crucible vessel. Thus, the crystal growth device may also have multiple holding plates. One seed crystal or a plurality of seed crystals may be arranged on each of the plurality of holding plates, respectively, for growing semiconductors.

When the holding plate is a multi-part holding plate, it is preferred that the holding plate parts of the multi-part holding plate are formed such that they can be arranged on the source material for growing the semiconductor. Preferably, the holding plate parts are formed such that a seed crystal can be arranged on at least one of the holding plate parts on the side facing the crucible lid, so that desublimation, i.e., deposition of the source material, which has changed into its gas phase, on the seed crystal is enabled for growing the semiconductor. The holding plate parts of the multi-part holding plate are placed on the source material for growing the semiconductor, so that the multi-part holding plate is then arranged at a distance from the crucible bottom between the source material and the crucible lid.

For example, the holding plate parts may be formed such that one holding plate part is in the form of a disk and another holding plate part is in the form of a ring, wherein the outer diameter of the disk is smaller than the inner diameter of the ring. The disk can then be arranged in the ring. Through the free area or space formed between the disk and the ring, the gaseous source material for growing the semiconductor can flow toward the crucible lid. The seed crystal can then be arranged on the disk, for example, so that the gaseous source material can flow past and desublimate on the side surfaces of the seed crystal.

If the holding plate of the crystal growth device is a multi-part holding plate, it is preferred if the holding plate parts are formed in such a way that they can maximally jointly cover a closed area of between 95% and 25%, in particular between 80% and 40%, preferably between 70% and 50% of the crucible bottom or the surface of the source material when growing the semiconductor. Accordingly, when growing the semiconductor using a multipart holding plate, preferably between 5% and 75%, in particular between 10% and 60%, preferably between 30% and 50% of the surface area of the source material is not covered, i.e., is exposed, when growing the semiconductor. The maximum closed area that can be fabricated by arranging the at least two holding plates next to each other should therefore preferably be smaller than the base area of the crucible bottom. In this way, it can be achieved that free spaces are created when the at least two holding plate parts are arranged on a source material in the crucible vessel. Through the free spaces, gaseous source material can flow in the direction of the crucible lid and desublimate on the seed crystal.

The one-piece or multi-piece holding plate can, for example, comprise W, tungsten carbide (WC), TaC, and/or tantalum nitride (TaN). A holding plate made of these materials is comparatively stable, even with comparatively low thicknesses of a few millimeters. At the same time, a holding plate made of the aforementioned materials is heat resistant even at the typical high growth temperatures of semiconductors such as AlN and SiC of over 2000° C. Preferably, the holding plate has a thickness of 0.01 mm to 10 mm, in particular of 0.05 mm to 5 mm, preferably of 0.1 mm to 1 mm. If the holding plate is a multi-part holding plate, correspondingly, preferably, the holding plate parts each have a thickness of from 0.01 mm to 10 mm, in particular from 0.05 mm to 5 mm, preferably from 0.1 mm to 1 mm. In particular, holding plates with a thickness of 0.1 mm to 1 mm made of W, WC, TaC, and/or TaN can still be machined comparatively well, for example cut or drilled through, and are comparatively stable so that a seed crystal can be arranged securely on the holding plate for growing the semiconductor. When the holding plate is formed to be arranged on the rim of the crucible for growing the semiconductor, it is preferred when the thickness of the holding plate is from 0.5 mm to 10 mm, for example from 0.5 mm to 3 mm or from 1 mm to 5 mm. When the holding plate is formed to be arranged on the source material during growth of the semiconductor, the holding plate may be comparatively thinner and have a thickness that is, for example, from 0.01 mm to 5 mm, for example from 0.01 to 2 mm or from 0.01 mm to 1 mm. A holding plate that is arranged on the source material may be comparatively thinner, because it need only be suitable for allowing controlled gas flow at predefined areas or locations. A holding plate placed on the crucible rim at a distance above the source material should further be stable enough not to break due to the weight force of the seed crystal and the semiconductor to be grown.

The crystal growth device may further comprise a pedestal for holding the seed crystal, e.g., for holding the seed crystal loosely arranged on a seed holder. A pedestal may be configured as a seed holder that is configured for loosely holding the seed crystal, i.e., without providing a fixed attachment by using a binder or the like. Preferably, the pedestal has a height of from 0.1 mm to 10 mm, in particular from 0.5 mm to 8 mm, preferably from 1 mm to 5 mm. Preferably, the pedestal for growing the semiconductor can be arranged on the side of the one-piece or multi-piece holding plate facing the crucible lid. A pedestal for holding the seed crystal has the advantage that the material supply for growing the semiconductor can be improved, since the seed crystal is located at a comparatively greater distance from the holding plate. Indeed, it can be assumed that the material supply of gaseous source material directly on the surface of the holding plate facing the crucible lid is comparatively lower. This applies in particular to those locations on the holding plate which are comparatively far away from a feedthrough or a free surface of a holding plate or a free space between two holding plate parts. It can be further assumed that the greater the distance from the holding plate in the direction of the crucible lid, the more homogeneous is the distribution of the gaseous source material. If the seed crystal is now arranged at a distance from the holding plate by means of the pedestal, it can be achieved that the seed crystal is exposed to a comparatively higher material supply, so that more gaseous source material can be desublimated at the seed crystal. In particular, the height of the pedestal can be used to set a ratio of lateral and vertical growth rates. Thus, in the case of a Wurtzite crystal, a ratio of the growth rate on the m surface to a growth rate on the c surface, in particular, can be set. The seed crystal can be arranged loosely on the pedestal or be attached to the pedestal.

Preferably, the pedestal is configured such that it has a thermal conductivity λ of 30 W/(m*K) or less, in particular of 15 W/(m*K) or less, preferably 10 W/(m*K) or less, for example of 5 W/(m*K) or less, particularly preferably of 1 W/(m*K) or less, at least in the direction of that surface of the pedestal on which the seed crystal is to be arranged for growing the semiconductor. In this way, the seed crystal arranged on the pedestal can be thermally isolated from the holding plate during the growth of the semiconductor, so that no or at least a comparatively reduced heat transport takes place between the holding plate and the seed crystal. In this way, it can be achieved that a comparatively large temperature difference between a nucleation temperature of the seed crystal and a source temperature of the source material are achieved. The temperature difference can be, for example, 50 K to 150 K when growing the semiconductor.

For example, the pedestal may comprise TaC and/or W, or may be made of one or both of these materials. Tungsten has a thermal conductivity of about 150 W/(m*K) at room temperature and a thermal conductivity of about 100 W/(m*K) at a growth temperature of 2000° C. Tantalum carbide has a thermal conductivity of about 30 W/(m*K) at room temperature and a thermal conductivity of about 40 W/(m*K) at a 2000° C. growth temperature. Because of the comparatively lower thermal conductivity, TaC is particularly suitable as a material for the pedestal. However, a pedestal made of tungsten has the advantage that it is comparatively easier to manufacture with a comparatively high porosity and comparatively small pores.

A pedestal with low thermal conductivity at least in the direction of that surface of the pedestal on which the seed crystal is to be arranged for growing the semiconductor can in fact be formed in particular from a porous metal or a porous intermetallic compound. Because of the pores, heat is transported in particular essentially along the walls enclosing the pores in a cell-like manner. In a porous material, therefore, less material is available along which heat can be transported. A high porosity can thus comparatively reduce the thermal conductivity.

Preferably, a porous material of the pedestal has a porosity of 50% or more. For example, a porous material of the pedestal may have a porosity from 50% to 99%, preferably from 90% to 99% or from 95% to 99%. Generally, it is preferred if the average pore size is from 1 μm and 1000 μm.

The porous metal or porous intermetallic compound may have, for example, W, WC, TaN and/or TaC. A pedestal with high porosity has the advantage that it is possible to reduce the thermal conductivity of the material used below that of the bulk material without pores. In particular, the relationship between the thermal conductivity and the porosity is approximately linear for a pore size of 1 μm and 1000 μm. For example, tungsten at a porosity of 90% with a pore size of 1 μm and 1000 μm and at room temperature has 10% of the original thermal conductivity, i.e., about 15 W/(m*K).

Alternatively, a pedestal with a thermal conductivity at least in the direction of that surface of the pedestal on which the seed crystal is to be arranged for growing the semiconductor may also be realized by a layer system comprising several layers of a metal or an intermetallic compound, for example W, WC, TaN and/or TaC. At least one of the layers of the layer system may be porous. The low thermal conductivity A of 30 W/(m*K) or less, in particular of 15 W/(m*K) or less, preferably 10 W/(m*K) or less, for example of 5 W/(m*K) or less, particularly preferably of 1 W/(m*K) or less is thereby realized in particular in the stacking direction of the layers of the layer system. The interfaces of the layers can function as heat barriers. For example, heat in the layer system may be reflected at the interfaces so that effectively a reduced amount of heat is transported through the layer system. As few as two layers may be sufficient to achieve low thermal conductivity, for example when TaC is used. However, it is preferred that the layer system consists of more than two layers, for example from two to ten layers.

Optionally, the crystal growth device may comprise a crystal growth mold. The crystal growth mold comprises a mold body having inner side walls that are configured to enclose a growth volume in which the semiconductor can grow. In particular, the crystal growth mold is configured to predefine with its inner side walls a lateral shape and/or lateral diameter of the semiconductor to be grown with the crystal growth device. The mold body of the crystal growth mold can be made of or can comprise W or TaC. Accordingly, the crystal growth mold may also be referred to as a crystal channel, since it provides a growth channel in which the semiconductor can grow. In particular, when using a crystal growth mold for fabricating a semiconductor, a start (bottom) diameter of the semiconductor may be determined by the size of the seed crystal and an end (top) diameter of the semiconductor may be determined by the upper diameter of the mold body.

The mold body of the crystal growth mold can be made of one piece. Alternatively, the mold body of the crystal growth mold can be comprised of several pieces that can be arranged so that their inner side walls together enclose a growth volume in which the semiconductor can grow.

It is possible that the mold body of the crystal growth mold has one or more feedthroughs in its side walls so that gaseous source material can enter the enclosed growth volume through the one or more feedthroughs in order to desublimate on the seed crystal. It is particularly preferred that the mold body of the crystal growth mold has an upper mold opening facing the crucible lid when the crystal growth mold is arranged on the holding plate so that gaseous source material can enter the enclosed growth volume through the upper mold opening in order to desublimate on the seed crystal.

Preferably, the mold body has a circular shape and is configured for enabling a growth of a semiconductor having a circular cross-section. Yet, other shapes such as a rectangular shape are also possible. Preferably, the mold body has a height of at least 5 mm, e.g., of 5 mm to 30 mm. For example, the mold body may have an inner diameter that ranges from 1 mm to 115 mm, preferably, from 10 mm to 70 mm. Preferably, the mold body has a maximum inner diameter that ranges from 1 mm to 115 mm, preferably, from 10 mm to 70 mm. Preferably, the maximum inner diameter is present at least at the top of the mold body, i.e. at that side of the mold body that faces away from the holding plate when the crystal growth mold is arranged onto the holding plate. For example, in case the inner diameter increases from a mold body bottom to a mold body top, the maximum inner diameter is present at least at the top of the mold body. Yet, in case the mold body defines a growth volume of cylindrical shape, the inner diameter is constant from mold body bottom to the top such that the mold body has a constant inner diameter that ranges from 1 mm to 115 mm, preferably, from 10 mm to 70 mm.

The Table below exemplary depicts different geometry values for different crystal growth molds that can be used with the crystal growth device described herein. Moreover, the Table below depicts geometry values of semiconductors that can be fabricated with crystal growth molds that realize the geometry values given in the Table.

In particular, in the left column, a height of various crystal growth molds is given in millimeter and is exemplary selected to be either 5 mm, 10 mm, or 30 mm. The second column provides different bottom diameters in millimeters for seed crystals that can be used in conjunction with the respective crystal growth molds. The exemplary selected bottom diameters are 1 mm, 10 mm, and 50.8 mm. Preferably, the seed crystals do not form part of the crystal growth device.

The third column provides angles of inclination of the mold bodies (or the growth volumes) given in degrees that are exemplary selected to be 10° or 45°, e.g. they can exemplary range from 10° to 45°. With this angle of inclination, the growth volume widens so that an inner diameter increases from bottom to top. The last column (column on the right) provides different top diameters of semiconductors that can be grown in crystal growth molds that realize the corresponding heights (left column) and angles of inclination (third column) when starting with seed crystals having the correspondingly provided bottom diameters. The top diameters that can be obtained are 3 mm, 11 mm, 12 mm, 20 mm, 14 mm, 30 mm, 54 mm, 71 mm, 21 mm, 70 mm, 61 mm and 111 mm, respectively.

| Height | D bottom | Inclination | D top |
|---|---|---|---|
| [mm] | [mm] | [°] | [mm] |
| 5 | 1 | 10 | 3 |
| 5 | 1 | 45 | 11 |
| 5 | 10 | 10 | 12 |
| 5 | 10 | 45 | 20 |
| 10 | 10 | 10 | 14 |
| 10 | 10 | 45 | 30 |
| 10 | 50.8 | 10 | 54 |
| 10 | 50.8 | 45 | 71 |
| 30 | 10 | 10 | 21 |
| 30 | 10 | 45 | 70 |
| 30 | 50.8 | 10 | 61 |
| 30 | 50.8 | 45 | 111 |

In case the mold body has or encloses a bottom mold opening that is located in a bottom side of the mold body, the diameter of such a bottom mold opening may range from 1 mm to 55 mm, preferably, from 10 mm to 50 mm. Preferably, the inner diameter increase from the bottom to the top of the mold body to implement a funnel-like or cone-like shape. When growing a semiconductor in the growth volume provided by the mold body, a diameter of the semiconductor may thus steadily increase. For example, it is possible to use a seed crystal having a diameter of 1 mm to 55 mm such that a bottom diameter of a fabricated semiconductor may be 1 mm to 55 mm, respectively. Assuming an opening angle of the mold body of 10° to 45° it may be possible to fabricate a semiconductor having an upper diameter of 1 mm to 115 mm. As an example, when starting with a seed crystal diameter of 1 mm and assuming an opening angle of 10° to 45° of the mold body side walls, a semiconductor with an upper diameter of 1 mm to 11 mm may be achieved. Considering a seed crystal with a diameter of 10 mm or 50.8 mm, a three inch or 100 mm upper diameter of a semiconductor may be achieved when assuming a height of the growth volume, i.e. along a direction pointing perpendicular to the holding plate, of 10 mm and 30 mm, respectively.

Accordingly, the inner diameter of the mold body, i.e., the diameter of the growth volume, may vary depending on whether the sidewalls defining the growth volume are straight, e.g., defining a cylindrically shaped growth volume or whether the sidewalls defining the growth volume are inclined, i.e., defining a conically shaped growth volume with its tapered end pointing towards the holding plate. Alternatively, the sidewalls defining the growth volume may be curved, e.g., defining a growth volume shaped as a semi-sphere or the like.

In particular, the crystal growth mold may be configured to be arranged on the holding plate such that the semiconductor can grow by desublimation of gaseous source material but limited to its lateral sides, i.e., towards the crucible inner side walls, by the inner side walls of the mold body. In case, the crystal growth mold is open towards the crucible lid when being arranged on the holding plate, growth of the semiconductor is limited to the semiconductor's lateral sides but not perpendicular to the holding plate, i.e., towards the crucible lid.

The inner side walls of the mold body can be straight, i.e., perpendicular to the holding plate, when being arranged on the holding plate. Alternatively, the inner side walls of the mold body can be inclined or curved with respect to the holding plate, when being arranged on the holding plate. For example, it is preferred that the inner side walls of the mold body are inclined with respect to a surface of the holding plate facing the crucible lid at an angle of at least 45°, e.g., of at least 60° such as at least 70°. Yet, it may be possible that the inner side walls of the mold body are inclined with respect to the surface of holding plate at an angle smaller than 45°. However, generally, it is preferred that the inner side walls of the crystal growth mold are inclined with respect to the surface of holding plate at an angle of at least 10°. In other words, an inclination of the inner side walls of the mold body to a direction perpendicular to the holding plate may be 10° or more, e.g., 45° or more, such as even 65° or more. Preferably, the inclination of the inner side walls of the mold body is such that the growth volume is increased in comparison to a cylindrically shaped mold body. In other words, the inclination of the inner side walls of the mold body is such that the side walls of the mold body are moved away from each other and not towards each other. Yet, in some specific embodiments it may even be advantageous if the side walls of the mold body are inclined towards each other. In this case it is preferred that the mold body is comprised of several pieces that can be moved apart of growth of the semiconductor in order to remove the semiconductor from the mold body.

Each of the straight, inclined or curved inner side walls enclosing a growth volume in which the semiconductor can grow has the advantage that the shape of the lateral sides and/or the lateral diameter of the semiconductor can be determined, i.e., it can be predefined at which angle or shape the semiconductor grows at its sides relative to the holding plate. Moreover, it can be ensured that a shape of the lateral sides of the semiconductor can be substantially uniform in all lateral directions.

The crystal growth mold can be configured such that a seed crystal, e.g., arranged on a pedestal, can be arranged within the growth volume formed by the mold body's inner side walls. To this end, it is possible that the mold body has a closed bottom side. With its bottom side, the crystal growth mold can be placed loosely onto the holding plate. The seed crystal e.g., arranged on a pedestal, can then be arranged inside the growth volume by inserting the seed crystal, e.g., arranged on a pedestal, into the growth volume. The seed crystal e.g., arranged on a pedestal, may be loosely arranged inside the mold body within the growth volume.

Alternatively, the crystal growth mold can be configured such that the mold body can laterally enclose a seed crystal, e.g., arranged on a pedestal. For example, the mold body can be configured such that it has a bottom mold opening that is located in a bottom side of the mold body and sized so that a seed crystal, e.g., arranged on a pedestal can be arranged in the bottom mold opening. Thereby, the seed crystal e.g., arranged on a pedestal is arranged within the growth volume formed by the mold body's inner side walls. In this case, the growth volume is limited by the holding plate at its bottom and by the inner side walls of the mold body on its sides. The seed crystal e.g., arranged on a pedestal is then arranged in direct contact with the holding plate.

Alternatively, the crystal growth mold can be configured to be arranged onto a pedestal that has a larger lateral diameter than a seed crystal to be used. In this case, for growing the semiconductor with the crystal growth device, the pedestal is arranged on the holding plate and the crystal growth mold is arranged onto the pedestal. Preferably, the mold body comprises a bottom mold opening that is located in a bottom side of the mold body and is sized so that a seed crystal can be arranged onto the pedestal and inside the bottom mold opening. Thereby, the seed crystal can be arranged within the growth volume formed by the mold body's inner side walls and onto the pedestal to then be enclosed by the mold body. Moreover, in this configuration, the crystal growth mold is not in direct contact with the holding plate.

The mold body's sidewalls may have a lateral thickness of, e.g., 50 μm to 5 mm. The thickness of the mold body's sidewalls may not be constant but may vary from 50 μm to 5 mm along a height of the mold body. For example, the sidewalls may be thicker at the bottom side of the mold body and may be thinner at the top of the mold body or vice versa. Accordingly, an outer diameter of the mold body may dependent on the inner diameter as well as the side wall thickness. Yet, it is also possible that the mold body's side walls have a constant lateral thickness.

In the framework of this description, a semiconductor is in particular a III-V semiconductor such as AlN or a SiC semiconductor. Preferably, the semiconductor is single crystalline and in particular a single crystalline bulk crystal. The crystal growth device is particularly suitable for the production of a semiconductor from the vapor phase, in particular by means of physical vapor phase transport optionally in combination with hybrid vapor phase epitaxy (HYPE). When the crystal growth device is used to grow the semiconductor, it is preferred that the seed crystal is loosely arranged on the holding plate. Alternatively, however, the seed crystal may be attached to the holding plate, e.g., with a binder, especially a ceramic binder.

The crucible of the crystal growth device may comprise or consist of W and/or TaC and/or graphite (C). In particular, the crucible is made of a material having a melting point of 3000° C. or more. The crucible may have a crucible sidewall that is cylindrical in shape. However, the crucible may also have a plurality of crucible sidewalls, for example three or four crucible sidewalls, such that the crucible has a triangular or rectangular pedestal.

The heater is preferably an inductive heater comprising one or more induction coils. The induction coil may extend around the crucible to inductively heat source material arranged in the crucible vessel so that it sublimates.

According to the invention, a method for growing a semiconductor from a gas phase of a source material is also proposed. The method comprises the steps of:
providing a crystal growth device according to at least one of the preceding claims,
placing a source material for the semiconductor into the crucible vessel,
arranging the holding plate above the source material so that the holding plate is spaced from the crucible bottom of the crucible vessel,
arranging at least one seed crystal on the surface of the holding plate facing away from the source material,
arranging the crucible lid on the crucible vessel so that the holding plate is located between the source material and the crucible lid, and
heating the source material so that the source material at least partly changes into the gas phase and flows towards the crucible lid, so that the source material which has changed into its gas phase can desublimate on the seed crystal.

Accordingly, the proposed method can be carried out with the crystal growth device as described above.

The method has the advantage that it enables comparatively slow growth on a surface facing the crucible lid, i.e., in particular on a c-surface of the seed crystal with Wurtzite crystal structure, especially at low supersaturation but high growth temperature. Slow growth on a surface facing the crucible lid can be achieved by the fact that the material supply on the surface of the seed crystal facing the crucible lid, i.e., for example, the c-surface, is comparatively lower. This is particularly due to the fact that the surface of the seed crystal facing the crucible lid is turned away from the source material. The gaseous source material first flows past the side surfaces of the seed crystal, which are in the gas flow when the semiconductor is grown. Only after the gaseous source material has flowed past the side surfaces of the seed crystal and has not desublimated at the side surfaces, can the gaseous source material reach the surface of the seed crystal facing the crucible lid. However, the likelihood of this can be significantly reduced compared to conventional growth methods in which the seed crystal is located on the crucible lid with its c surface facing the source material.

The fact that the seed crystal can be arranged loosely and freely on the holding plate in the method means that additional stresses in the semiconductor can be reduced and its crystal quality further improved. Alternatively, the seed crystal may also be attached to a seed holder. Due to the arrangement on the holding plate, a comparatively good crystal quality can still be achieved even if the seed crystal is attached to a seed holder.

The source material used in the process is preferably a polycrystalline source material for the semiconductor. The source material is preferably solid and can be introduced into the crucible vessel in powder form. The source material may also be powdered but compressed before being introduced into the crucible vessel. In particular, the source material has the materials of the semiconductor to be grown. For example, the source material may have polycrystalline AlN, for the fabrication of an AlN semiconductor. Alternatively, the source material may comprise polycrystalline SiC, for the fabrication of a SiC semiconductor. Preferably, the source material is configured to sublimate by heating, i.e., to change directly from its solid aggregate state to its gaseous aggregate state. The semiconductor grows on the seed crystal in particular by the gaseous source material that desublimates on the seed crystal, i.e., changing from its gaseous aggregate state to its solid aggregate state.

In the process, a comparatively high source temperature of up to 2400° C. can be used. This is made possible by the fact that the holding plate can be used to reduce the available evaporation area of the source material or the amount of gaseous source material that is reached per unit of time of the crucible lid. Due to the comparatively high source temperature of up to 2400° C., a comparatively high nucleation temperature of up to 2300° C. can also be used in the process. This has the advantage that a comparatively large amount of sublimated source material can be provided locally by the holding plate, which flows past the side surfaces of the seed crystal and can desublimate there. Thus, a comparatively high lateral growth rate, e.g., on the m surfaces, can be achieved. Furthermore, a growth rate can be achieved on the surface of the seed crystal facing the crucible lid, i.e., in particular the c-surface, which is comparable to growth rates on c-surfaces achieved in conventional cultivation methods. However, the c-surface may have a comparatively higher surface temperature in the process described herein. The comparatively high nucleation temperature, particularly at the surface of the seed crystal facing the crucible lid, particularly favors comparatively high surface mobility and reduced formation of dislocations in the semiconductor. As a result, the crystal quality of the semiconductor can be further improved.

In the process, a temperature difference between a nucleation temperature of the seed crystal and a source temperature of the source material, which is from 50 K to 150 K, may occur at the seed crystal during deposition of the source material which has changed to its gas phase. The comparatively large temperature difference has the advantage that the semiconductor can grow at a comparatively high growth rate, especially in the lateral direction on a side surface of the seed crystal. In particular, the nucleation temperature can be from 2200° C. to 2300° C. and/or the source temperature can be from 2250° C. and 2400° C.

Preferably, there is a temperature gradient in the crucible between the comparatively hotter source material and the comparatively colder crucible lid. In this gas flow of the sublimated, gaseous source material caused by the temperature gradient, the semiconductor grows on the seed crystal. The seed crystal thereby becomes part of the semiconductor as the gaseous source material desublimates on the seed crystal. The more gas flow provided, the higher the material supply can be for the semiconductor and the higher the growth of the semiconductor can be. Since the side surfaces of the seed crystal are in the gas flow and the surface facing the crucible lid is away from the gas flow, the growth at the side surfaces, e.g., at the m surfaces of the seed crystal, can be higher than at the surface of the seed crystal facing the crucible lid, e.g., at the c surface. The gas flow can be affected by the temperature in the source region, the size and location of the feedthroughs and openings in the at least one holding plate, and the temperature gradients in the crucible.

In contrast to the method described here, in conventional growth methods using physical gas phase transport, growth on the c surface is comparatively higher at essentially the same surface temperature because it is opposite the source material and the gaseous source material directly impinges on the c surface.

In the method, it is preferred if the seed crystal has a substantially circular cross-sectional area and/or rounded side edges. Rounded side edges can be achieved, for example, by polishing the seed crystal. Rounded side edges are preferred because they can be comparatively low in defects. If the rounded side edges are comparatively low in defects, few defects can also be propagated into the volume of the semiconductor. A circular cross-sectional area is preferred because it is then particularly easy to realize uniform growth conditions at the seed crystal, i.e., there is no preferred location at which growth is comparatively higher than at other locations. Accordingly, substantially the same local conditions can exist at each location and growth can occur substantially uniformly at each of the side surfaces.

A seed crystal used in the method preferably has a thickness of at least 300 μm, for example 700 μm or more, preferably from 300 μm to 2000 μm.

Dislocations with a Burgers vector perpendicular to the c-plane <0001> are typically called c-type dislocations because Burgers vector is perpendicular to the c-plane. Here, the line defect is perpendicular to the c-plane and thus parallel to the Burgers vector, which is why the dislocations are also called screw dislocations. Furthermore, there are dislocations with a Burgers vector in the c-plane 1/3<11-20> which are called a-type dislocations because the Burgers vectors are perpendicular to a-planes. Due to symmetry, there are 3 or 6 equivalent Burgers vectors for a-type dislocations. There are a-type dislocations with dislocation line perpendicular to the c-plane which are also called step dislocations because the dislocation line is perpendicular to the Burgers vector here. Furthermore, there are a-type dislocations with dislocation line in the c-plane which are also called basal plane dislocations. Since the Burgers vector is perpendicular to the dislocation line, basal plane dislocations are nevertheless also step dislocations. Further explanation of dislocations with a c-type component and dislocations with an a-type component can be found in the articles B. Raghothamachar et al, “Defect Generation Mechanisms in PVT-grown AlN Single Crystal Boules,” Materials Science Forum, 740-742, 91-94, 2013 and K. Semennikov et al., “Analysis of Threading Dislocations in Wide Bandgap Hexagonal Semiconductors by Energetic Approach,” Materials Science Forum, 457-460, 383-386, 2004 5.

In the method, it is further preferred that the seed crystal has substantially no dislocations having a Burgers vector with a component along the <0001>-direction, in particular 10 cm⁻² or less, for example 0.1 cm⁻² or less dislocations having a Burgers vector with a component along the <0001>-direction, preferably 0 cm⁻² dislocations having a Burgers vector with a component along the <0001>-direction. The seed crystal can be a spontaneously nucleated crystal without dislocations with c-type component. However, the seed crystal can also be a crystal fabricated in a previous iteration according to the method described herein. The seed crystal can then be used in the process to fabricate a semiconductor that has a larger diameter compared to the seed crystal. The semiconductor thus fabricated can again be used as a seed crystal in a subsequent iteration of the process to produce a semiconductor with again a larger diameter, until the target diameter has been achieved. Since it is possible in the method to fabricate essentially no dislocations with a c-type component, and the seed crystal also has essentially no dislocations with a c-type component, it is possible in this way to produce a semiconductor that has essentially no dislocations that have a Burgers vector with a component along the <0001>-direction, in particular 10 cm⁻² or less, for example 0.1 cm⁻² or less dislocations having a Burgers vector with a component along the <0001>-direction, preferably 0 cm⁻² dislocations having a Burgers vector with a component along the <0001>-direction.

In the seed crystal, line defects may be present which are perpendicular to the growth direction, so-called basal plane dislocations. However, since these line defects are not inherited in the lateral direction, a semiconductor can be grown from such a seed crystal which has a comparatively small proportion of dislocation line perpendicular to the growth direction.

Preferably, in the method, during the deposition of the source material that has changed to its gas phase on the seed crystal, a ratio of an m-growth rate of the semiconductor on its m-surface and a c-growth rate of the semiconductor on its c-surface is 0.6 or more, particularly is 0.8 or more, preferably is 1.0 or more, for example is from 0.8 to 2.0 or from 1, 0 to 1.6. For example, in the process, the c-growth rate of the semiconductor may be 250 μm/h or less, for example from 100 μm/h to 200 μm/h. In particular, the growth rate on an m surface is greater than 100 μm/h and in particular greater than 180 μm/h or 200 μm/h and in particular may be from 100 μm/h to 250 μm/h.

In the method, arranging the at least one seed crystal on the surface of the holding plate facing away from the source material may comprise that the seed crystal loosely rests on the holding plate during the growth of the semiconductor. Compared with the use of a seed crystal fixed on a seed holder, as used in the standard growth method mentioned at the beginning with the seed holder arranged on the crucible lid, this has the advantage that no stresses arise at high temperatures due to different expansion of the seed crystal and the seed holder, which are relieved by dislocation formation. It is also possible to prevent the seed crystal and seed holder from shrinking differently during cooling and the seed crystal from being under stress again. The stresses created during cooling cannot usually be relieved because dislocations are not formed at low temperatures. The loose arrangement of the seed crystal on the holding plate therefore has the advantage that no stresses are generated during heating due to different expansion coefficients of the seed crystal and seed holder, which are relieved by dislocation formation at high temperatures. Therefore, the dislocation densities in the fabricated semiconductor can be comparatively lower. In the method, the seed crystal may be arranged on a pedestal comprising W, WC, TaC and/or TaC, for example, and may be arranged on the holding plate together with the pedestal.

In the method, arranging the holding plate in the crucible may comprise arranging the holding plate on the source material during growth of the semiconductor. For example, at least two holding plate parts of a multi-part holding plate may be arranged in the crucible and may be arranged on the not-yet-sublimated source material during growth of the semiconductor. At least one seed crystal may be arranged on each of at least two of the at least two holding plate parts. The process can be used to fabricate a plurality of semiconductors simultaneously. The production of semiconductors can thus be parallelized and the number of semiconductors fabricated can be multiplied during a certain period of time. With the method, semiconductors can thus be manufactured comparatively efficiently and with reduced time expenditure.

As an alternative to arranging the holding plate directly on the source material, the method may provide that placing the holding plate over the source material comprises arranging the holding plate on a crucible rim of the crucible vessel. The crucible lid is then placed over the seed crystal and arranged on the holding plate to provide a closed growth space.

In the method, it is preferred that arranging the at least one seed crystal comprises arranging the seed crystal on a pedestal on the holding plate having a thermal conductivity λ of 30 W/(m*K) or less at room temperature and/or at a growth temperature of 2000° C., in particular of 15 W/(m*K) or less, preferably 10 W/(m*K) or less, for example of 5 W/(m*K) or less, particularly preferably of 1 W/(m*K) or less at least in the direction of that surface of the pedestal on which the seed crystal is arranged. This has the advantage that only a comparatively reduced heat transport can take place between the holding plate and the seed crystal. The seed crystal is, so to speak, thermally decoupled or isolated from the holding plate. In this way, a comparatively high temperature gradient can be achieved between the source material and the seed crystal.

Preferably, a nitrogen (N₂) atmosphere is provided in the crucible in which the semiconductor is grown. Alternatively, N₂ may be mixed with other substances, such as argon (Ar). In the method, polycrystalline semiconductor material can form at the crucible lid, which in turn may be reused as source material.

According to the present invention, a semiconductor is proposed, in particular a single-crystal semiconductor bulk crystal comprising AlN or SiC, having in at least 90%, for example 95% or more or 99% or more of its volume substantially no dislocations having a Burgers vector with a component along the <0001>-direction, in particular 10 cm⁻² or less, for example 0.1 cm⁻² or less having dislocations having a Burgers vector with a component along the <0001>-direction, preferably 0 cm⁻² having dislocations having a Burgers vector with a component along the <0001>-direction. The semiconductor may be an intermediate product in the fabrication of a semiconductor substrate. For example, a semiconductor substrate can be directly fabricated from the semiconductor without the use of another crystal growth process. However, the semiconductor can also be used to make a seed wafer that is used in a further crystal growth process for crystal growth of a semiconductor substrate. In particular, the semiconductor can be made of AlN or SiC.

Preferably, the semiconductor has a diameter in at least one direction of 10 mm or more, preferably 50 mm or more, in particular 100 mm or more. The semiconductor, preferably, has a thickness or crystal height of at least 5 mm, in particular of at least 10 mm, preferably, of at least 15 mm, in particular, from 5 mm to 25 mm. Such a semiconductor having these dimensions and having in at least 90%, for example 95% or more or 99% or more of its volume substantially no dislocations having a Burgers vector with a component along the <0001>-direction is particularly suitable for the fabrication of semiconductor substrates having a comparatively large diameter and a comparatively high crystal quality.

The semiconductor is preferably formed such that an asymmetric (10-12) reflex and/or a symmetric (0002) reflex, e.g., of X-ray radiation of a copper K-alpha emission, has a full width half-maximum (FWHM) of 12 arcseconds or less, measured with a spot size of at least 2 mm×10 mm, in particular of at least 2 mm×50 mm. In case X-ray radiation of a copper K-alpha emission, the X-ray radiation may be provided using a copper anode. In particular, the spot size may extend in one direction over an entire semiconductor surface. A semiconductor with a FWHM of 12 arcseconds or less has a comparatively high crystal quality, i.e., a comparatively low density of dislocations or stresses in the crystal volume.

In at least 90%, for example 95% or more or 99% or more of its volume, the semiconductor preferably has a c-lattice parameter that varies in a range of 0.00060 Å or less, preferably varies in a range of 0.00030 Å or less and/or has an a-lattice parameter that varies in a range of 0.00040 Å or less, preferably varies in a range of 0.00020 Å or less. When the semiconductor is made of AlN, depending on the measurement method, a c-lattice constant averaged over the volume of the AlN semiconductor may be 4.97940 Å and an a-lattice constant may be 3.11140 Å. In at least 90%, for example 95% or more or 99% or more of the volume of the semiconductor of, for example, AlN or SiC, a difference between a largest and smallest value for the a-lattice constant is 0.00040 Å or less and for the c-lattice constant is 0.00060 Å or less. Accordingly, the semiconductor exhibits a comparatively homogeneous a and c lattice constant, and is therefore particularly suitable for the fabrication of semiconductor substrates for high-performance opto-electronic and electronic semiconductor devices.

According to the invention, also a use of the above-described semiconductor is proposed for the manufacture of a semiconductor substrate, wherein the semiconductor substrate has, in at least 90%, for example 95% or more or 99% or more of its volume, substantially no dislocations having a Burgers vector with a component along the <0001>-direction, in particular 10 cm⁻² or less, for example 0.1 cm⁻² or less dislocations having a Burgers vector with a component along the <0001>-direction, preferably 0 cm⁻² dislocations having a Burgers vector with a component along the <0001>-direction. A semiconductor substrate may also be referred to as a semiconductor wafer.

The use of the semiconductor may include fabricating the semiconductor substrate by mechanically and/or chemically processing the semiconductor described above. Accordingly, semiconductor substrates with high crystal quality can be directly fabricated from the semiconductor.

Alternatively, fabricating the semiconductor substrate using the semiconductor described above may comprise first fabricating a seed wafer by mechanically and/or chemically processing the semiconductor, which is used to fabricate the semiconductor substrate in a crystal growth process. The seed wafer may be used to fabricate a semiconductor substrate by the method described above. This has the advantage that the seed disk need not be attached to a seed holder. This can prevent dislocations from forming in the semiconductor substrate due to the different thermal expansion coefficients of a seed holder and the seed wafer.

It is also possible that an alternative crystal growth method with a predominant growth on a c-surface of the seed wafer is used to fabricate a semiconductor substrate. An alternative crystal growth method with a predominant growth on a c-surface of the seed wafer may comprise, for example, that the seed wafer is arranged opposite to a source material in a crucible as in the scientific publications of C. Hartmann et al. cited in the introduction, so that there is a free viewing axis between the seed wafer and the source material. The semiconductor substrate then grows preferentially on the c-surface towards the source material, with a growth rate in the c-direction being comparatively large and in the indirection comparatively smaller.

According to the invention, it is also proposed a semiconductor substrate, in particular made of a bulk crystal comprising AlN or SiC, having in at least 90% of its volume, for example 95% or more or 99% or more, essentially no dislocations having a Burgers vector with a component along the <0001>-direction, in particular 10 cm⁻² or less, for example 0.1 cm⁻² or less having dislocations having a Burgers vector with a component along the <0001>-direction, preferably 0 cm⁻² having dislocations having a Burgers vector with a component along the <0001>-direction. A semiconductor or semiconductor substrate having substantially no dislocations having a Burgers vector with a component along the <0001>-direction have the advantage of having substantially no dislocations with c component or screw dislocations. This is advantageous because c-type dislocations have a comparatively high dislocation energy.

From a semiconductor substrate with essentially no dislocations with a Burgers vector with a component along the <0001>-direction, particularly high-performance vertical power electronic devices can be manufactured, which run in the c-direction, i.e., along a voltage applied during operation. Due to the essentially non-existent dislocations with a Burgers vector with a component along the <0001>-direction, leakage currents or voltage breakdowns can be reduced or even completely prevented in such vertical power electronics devices.

Preferably, the semiconductor substrate is made of AlN or SiC. It is further preferred that the semiconductor substrate has a diameter of 10 mm or more in at least one direction, preferably 50 mm or more, in particular 100 mm or more. An asymmetric (10-12) reflex and/or a symmetric (0002) reflex of the semiconductor substrate, preferably, has a FWHM of 12 arcseconds or less, measured with a spot size of at least 2 mm×50 mm or at least 2 mm×100 mm, preferably, of X-ray radiation of a copper K-alpha emission, e.g., emitted by a copper anode. Preferably, a c-lattice parameter varies in at least 90% of the volume of the semiconductor substrate, exemplified by 95% or more or 99% in a range of 0.00060 Å or less, preferably in a range of 0.00030 Å or less, and/or an a-lattice parameter varies in at least 90% of the volume of the semiconductor substrate, exemplified by 95% or more or 99% in a range of 0.00040 Å or less, preferably in a range of 0.00020 Å or less. Preferably, the semiconductor substrate has a thickness of 0.1 mm or more, exemplarily 0.5 mm or more or 1 mm or more. Preferably, the semiconductor substrate has a thickness of 250 μm to 1 mm. Preferably, the semiconductor substrate has a dislocation density of dislocation line perpendicular to the growth direction on a c surface of 10⁴ cm⁻² or less, e.g., of 10³ cm⁻² or less.

The semiconductor substrate may have a central region at the center of the semiconductor substrate and a peripheral region surrounding the central region. In the central region, a dislocation density of a-type line defects perpendicular to the growth direction on a c surface may be 10⁴ cm⁻² or less, e.g., of 10³ cm⁻² or less, and in the peripheral region, a dislocation density of dislocation line perpendicular to the growth direction on a c surface may be 10² cm⁻² or less.

When the above-described semiconductor substrate is made of AlN, it is particularly suitable for the production of LEDs, laser diodes, as well as for power electronics and high-frequency applications. In particular, the above-described semiconductor substrate made of AlN can be used to manufacture UV-C LEDs for disinfection applications.

It shall be understood that the aspects described above, and specifically the crystal growth device of claim 1, and the method of claim 6, have similar and/or identical preferred embodiments, in particular as defined in the dependent claims.

It shall be further understood that a preferred embodiment of the present invention can also be any combination of the dependent claims or above embodiments with the respective independent claim.

These and other aspects of the invention will be apparent from and elucidated with reference to the embodiments described hereinafter with reference to the drawings.

### BRIEF DESCRIPTION OF THE DRAWINGS

FIG. 1A: schematically and exemplary shows a crystal growth device for growing a semiconductor by means of physical gas phase transport as known from the prior art;

FIG. 1B:

shows the crucible of the crystal growth device described with reference to FIG. 1A separately and at the beginning of growing the semiconductor;

FIG. 1C: shows the crucible of the crystal growth device described with reference to FIG. 1A separately and at a comparatively later time instance during growth of the semiconductor;

FIG. 2: shows schematically a cut through a unit cell of a Wurtzite crystal parallel to a c-face;

FIG. 3A: schematically and exemplary shows in a longitudinal sectional view a crystal growth device for growing a semiconductor according to an embodiment of the present invention in operation and at the beginning of growing the semiconductor;

FIG. 3B: shows the crystal growth device described with reference to FIG. 3A in a longitudinal sectional view in operation at a comparatively later time instance during growth of a semiconductor;

FIG. 4A: schematically and exemplary shows in a longitudinal sectional-view, a crystal growth device for growing a semiconductor according to another embodiment of the present invention in operation and at the beginning of growing the semiconductor;

FIG. 4B shows the crystal growth device described with reference to FIG. 4A in a longitudinal sectional view in operation at a comparatively later time instance during a growth of a semiconductor;

FIGS. 5A to 5E: shows different schematically and exemplary illustrated holding plates that can be part of a crystal growth device described herein;

FIG. 6: shows a schematic flowchart illustrating a method of growing a semiconductor;

FIG. 7A schematically and exemplary shows in a longitudinal sectional view, a crystal growth device for growing a semiconductor according to another embodiment of the present invention in operation and at the beginning of growing the semiconductor;

FIG. 7B schematically and exemplary shows the crystal growth device described with reference to FIG. 7A in a longitudinal sectional view in operation at a comparatively later time instance during growth of a semiconductor;

FIG. 8A schematically and exemplary shows in a longitudinal sectional view, a crystal growth device for growing a semiconductor according to another embodiment of the present invention in operation and at the beginning of growing the semiconductor;

FIG. 8B schematically and exemplary shows the crystal growth device described with reference to FIG. 8A in a longitudinal sectional view in operation at a comparatively later time instance during growth of a semiconductor;

FIG. 9A schematically and exemplary shows in a longitudinal sectional view, a crystal growth device for growing a semiconductor according to another embodiment of the present invention in operation and at the beginning of growing the semiconductor; and

FIG. 9B schematically and exemplary shows the crystal growth device described with reference to FIG. 9A in a longitudinal sectional view in operation at a comparatively later time instance during growth of a semiconductor.

### DETAILED DESCRIPTION OF EMBODIMENTS

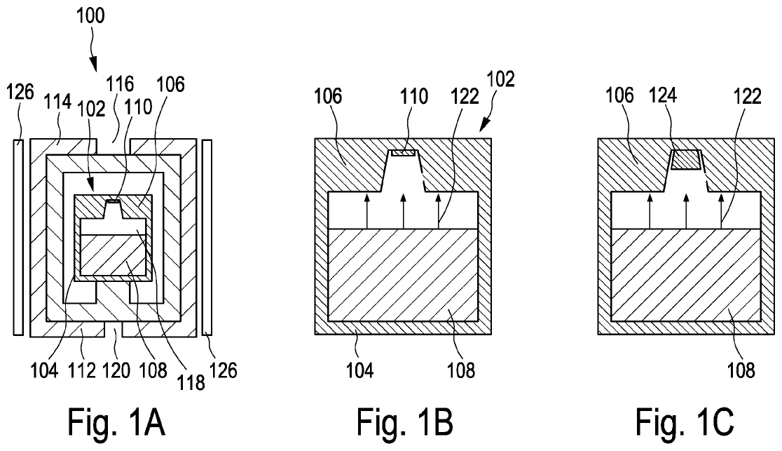

FIG. 1A shows a crystal growth device 100 for growing a semiconductor using physical gas phase transport as known from the prior art. The crystal growth device 100 comprises a crucible 102 having a crucible vessel 104 and a crucible lid 106. The crucible 102 may be made of W or TaC, for example. A source material 108 is arranged in the crucible vessel 104 for growing a semiconductor. A seed crystal 110 is arranged on the crucible lid 106 and opposite to the source material 108. The seed crystal 110 may be attached to a seed holder (not shown) by means of a ceramic binder, e.g., AlN-based, or by means of mechanical clamping. The seed holder may be attached to, or may be integral with, the crucible lid 106. Thus, there is a free line of sight between the seed crystal 110 and the source material 108. For example, the seed crystal may be made of AlN or SiC and the source material 108 may comprise polycrystalline AlN or SiC, respectively. In this case, the c-surface of the AlN or SiC seed crystal 110 is parallel to the surface of the source material 108 and facing the source material 108 so that sublimated source material 108 can impinge directly on the c-surface of the seed crystal 110 as it flows toward the crucible lid 106 due to a corresponding temperature gradient within the crucible 102. The source material 108 has less than 150 ppm wt. of oxygen. In the crucible 102 there is an atmosphere of 99.999% nitrogen at a pressure of 500 to 800 millibars.

The crucible 102 is arranged within a susceptor 112, which may be made of graphite, for example. Thermal insulation 114 is arranged around the susceptor 112. The thermal insulation 114 may comprise carbon fibers, for example. The thermal insulation 114 includes a first opening 116 on the side of the crucible lid 106, and a second opening 120 on the side of the crucible bottom 118. The first opening 116 is larger than the second opening 120, such that a temperature gradient is established in the crucible 102 between the crucible lid 106 and the crucible bottom 118 during growth of the semiconductor, which ensures that sublimated source material 108 flows toward the crucible lid 106. In particular, heat radiation is greater at the crucible lid 106 than at the crucible bottom 118, causing sublimated source material 122 to flow toward the crucible lid 106. A heater 126, comprising an induction coil, is arranged around the thermal insulation 114 and is configured to heat the source material 108 arranged in the crucible 102 so that it at least partly sublimates.

In the crystal growth device 100, the temperatures at the crucible lid 106 and the crucible bottom 118 can each be measured using an infrared pyrometer. Using the measured temperatures and additional simulations of the temperatures within the crucible 102, the temperature gradient within the crucible 102 can be adjusted by tuning the heating power of the heater 126.

Optionally, the thermal insulation 14 may be enclosed by a housing (not shown), which may be made of quartz, for example. If the crystal growth device 100 includes a housing, the heater 126 is preferably arranged such that an induction coil of the heater 126 circulates around the housing 210.

FIG. 1B shows the crucible 102 of the crystal growth device 100 separately and at the beginning of the growth of the semiconductor. The crucible vessel 104 holds source material 108, the crucible lid 106 is arranged on the crucible vessel 104, and the seed crystal 110 is arranged at the crucible lid 106 opposite the source material 108. To grow the semiconductor, the source material 108 is heated by the heater 126 in the crucible vessel 104 so that it sublimates. The sublimated gaseous source material 122 flows in the crucible 102 toward the crucible lid 106 and then impinges on the surface of the seed crystal 110 facing the source material 108, that is, in particular, on the c-surface thereof. Since the c-surface of the seed crystal 100 is arranged opposite the source material 108, the semiconductor grows at a comparatively high growth rate on the surface facing the source material, i.e. in particular on the c-surface, whereas the growth rate on the side surface, i.e. in particular on the m-surface, is comparatively lower. Thus, comparatively more iterations are necessary to achieve a certain target diameter of the semiconductor.

FIG. 1C shows the crucible 102 of the crystal growth device 100 separately at a comparatively later time during the growth of the semiconductor. At this point in time, growth of the semiconductor 124 towards the source material 108, i.e., in particular on the c surface, has already taken place on the seed crystal 110. Accordingly, the source material 108 has already been heated by the heater 126 so that it is sublimed and flows towards the crucible lid 106 due to the temperature gradient. The gaseous source material 122 is desublimated at the seed crystal 110 so that the semiconductor 124 has increased in volume, in particular in the direction of the source material 108, that is, in particular in its c-direction. In particular, an angle of diameter increase in the c-direction is comparatively small. In particular, an angle of diameter increase in the c-direction is the angle included between a lateral outer surface of the grown semiconductor and a normal vector of the c-surface. Since the supply of material at the side surfaces of the seed crystal 110, i.e., particularly at the m surfaces, is comparatively smaller, the diameter of the semiconductor 124 has increased only slightly compared to the growth in the direction of the source material 108. It is therefore generally necessary for the fabrication of a semiconductor substrate to already use a seed crystal or seed wafer that already has a comparatively large diameter, such as two inches or more.

A semiconductor substrate can be fabricated from a semiconductor grown by the crystal growth device 100 by sawing a slice from the semiconductor with a diamond saw having a grain size of, for example, 1 μm, and then chemically and mechanically polishing the slice, e.g., using SiO₂ at pH >10. In particular, the AlN or SiC semiconductor can be processed to fabricate therefrom a {0001} or {10-10} AlN or SiC substrate.

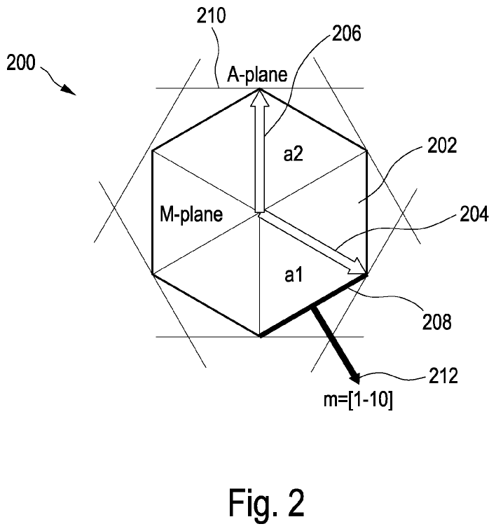

FIG. 2 schematically shows a cut through a unit cell 200 of a Wurtzite crystal parallel to a c-surface 202. The unit cell 200 may be, for example, the unit cell of an AlN or SiC crystal. The unit cell 200 is spanned by the unit vectors a1 204 and a2 206 and by the unit vector c. The unit vectors a1 204 and a2 206 have an angle of 120° to each other and are identical in magnitude. The unit vector c (not shown) is perpendicular to the unit vectors a1 204 and a2 206.

Furthermore, the m-surface 208 and the a-surface 210 of the Wurtzite crystal are drawn into the unit cell 200. Here, the unit vectors a1 204 and a2 206 point perpendicular to a-surface 210. Furthermore, a normal vector 212 to m-surface 208 is drawn. The m-surface 208 and the a-surface 210 are inclined to each other by an angle of 30°.

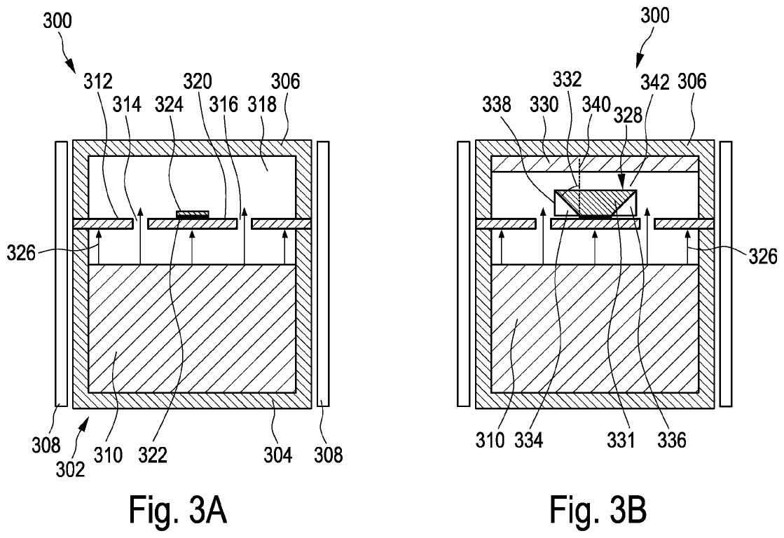

FIG. 3A shows a longitudinal sectional view of a crystal growth device 300 for growing a semiconductor according to an embodiment of the present invention. The crystal growth device 300 is shown, by way of example, in operation at the beginning of growing the semiconductor.

The crystal growth device 300 has a crucible 302, which may be made of W or TaC, for example. The crucible 302 includes a crucible vessel 304 and a crucible lid 306. Further, the crystal growth device 300 includes a heater 308, which may comprise one or more induction coils, and a holding plate 312.

A source material 310, preferably comprising polycrystalline AlN or SiC, is arranged in the crucible vessel 304. A holding plate 312 is supported on a crucible rim of the crucible vessel 304 and includes a plurality of feedthroughs 314, 316. The holding plate 312 may be made of W or TaC, for example, and may have a thickness of 0.01 mm to 10 mm, although a thickness of 0.1 mm to 1 mm is preferred. The crucible lid 306 is arranged on the holding plate 312 so that a closed gas space 318 is formed above the source material 310 in the crucible 302. This gas space 318 can be filled with a nitrogen atmosphere, for example.

On the surface 320 of the holding plate 312 facing the crucible lid 306, a seed crystal 324 is arranged on a pedestal 322. In particular, the pedestal 322 and the seed crystal 324 are arranged loosely on the holding plate 312 and are not fixedly connected thereto. The pedestal 322 preferably has a thickness of 1 mm to 5 mm and may be made of W, WC, TaN or TaC, for example. In particular, the pedestal 322 serves to increase the distance between the seed crystal 324 and the holding plate 312 so that the supply of sublimated source material 326 is increased during growth of the semiconductor. Further, the pedestal 322 serves to thermally isolate the seed crystal from the holding plate so as to realize a comparatively large temperature gradient between the seed temperature of the seed crystal and the source temperature of the source material.

The heater 308 is used to heat the source material 310 during operation of the crystal growth device 300, such that the source material 310 at least partially sublimates. The sublimated gaseous source material 326 flows toward the crucible lid 306 due to a temperature gradient within the crucible 302 and flows through the feedthroughs 314, 316 of the holding plate 312 on its way to the crucible lid 306. The gaseous source material 326 preferentially desublimates at the side surfaces of the seed crystal 324 that are in the gas flow of the gaseous source material 426. Since the holding plate 312 is arranged between the seed crystal 324 and the source material 308, and the seed crystal 324 has its c-surface facing the crucible lid 306, the material supply of sublimated source material 326 at the c-surface is comparatively less than at the side surfaces of the seed crystal 324. Accordingly, the semiconductor grows comparatively slower on the c-surface and comparatively more on the m-surface of the seed crystal 324, and thus comparatively fewer iterations are required to achieve a desired target diameter of the semiconductor. This may also reduce a likelihood that dislocations will be incorporated into the semiconductor. Additionally, the dislocation density in the semiconductor may be reduced by having the seed crystal 324 loosely and freely supported on the holding plate 312 so that thermal stresses due to different thermal expansion coefficients between the seed crystal and a seed holder, such as those used in the known crystal growth device described with reference to FIGS. 1A to 1C, are avoided.

The crystal growth device 300 may further comprise a susceptor and thermal insulation and a housing, wherein the susceptor and thermal insulation are preferably arranged between the crucible 302 and the heater 308. For example, the susceptor and thermal insulation may be formed as described with reference to FIGS. 1A to 1C. In particular, the device 300 may have the components of the crystal growth device 100 described with reference to FIG. 1A, except that the crucible 102 is replaced by the crucible 302 with the holding plate 312 arranged between the source material 310 and the crucible lid 306.

FIG. 3B shows the crystal growth device 300 in a longitudinal sectional view in operation at a later time during a growth of a semiconductor 328. At this time instance, polycrystalline semiconductor material 330, for example made of AlN or SiC, has already been deposited on the crucible lid 306. The polycrystalline semiconductor material 330 may be used, for example, as a source material for growing another semiconductor.

The semiconductor 328 already fabricated at the later time has a region 331 formed by deposition of source material 326 on the c surface of the seed crystal 324. Schematically indicated, an angle of diameter increase 332 in the c-direction is comparatively large. For example, the angle of diameter increase 332 in the c-direction may be greater than 15°, or greater than 20°, or greater than 30°. In particular, the angle of diameter increase 332 in the c-direction may be from 20° to 60°. In particular, the angle of diameter increase 332 is formed between an outer surface 338 of the semiconductor 328 formed by growth on the c surface and a normal vector 340 of the c surface 342 of the semiconductor 328.

The semiconductor 328 further includes lateral regions 334, 336 formed by lateral growth on the m surface of the semiconductor. Due to the comparatively high growth rate in the m-direction and the comparatively lower growth rate in the c-direction, the desired target diameter of the semiconductor 328 can be achieved with comparatively fewer iterations and a comparatively lower volume increase in the c-direction using the crystal growth device 300.

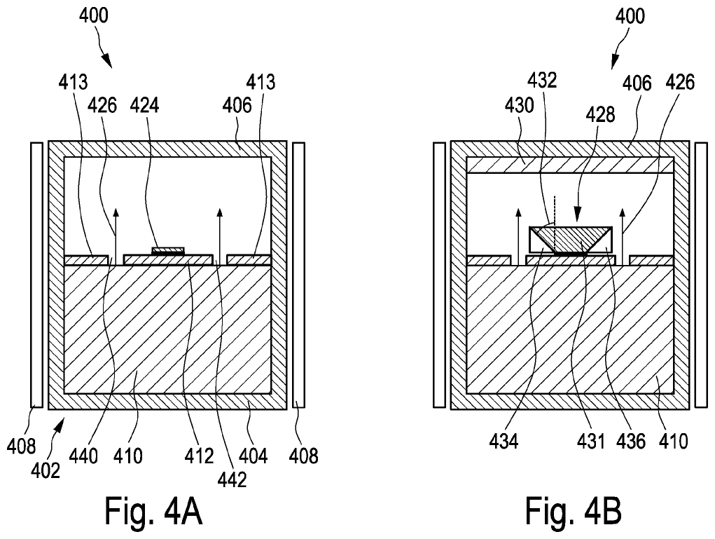

FIG. 4A shows a longitudinal sectional view of a crystal growth device 400 for growing a semiconductor 428 according to another embodiment of the present invention. The crystal growth device 400 includes a crucible 402, which may be formed in the same manner as the crucible 302 of the crystal growth device 300 described with reference to FIGS. 3A and 3B. Accordingly, the crucible 402 also has a crucible vessel 404 and a crucible lid 406. A source material 410 is arranged in the crucible vessel 404 during operation of the crystal growth device 400. The crystal growth device 400 further comprises a heater 408, which may be formed by or include one or more induction coils, for example.

Unlike the crystal growth device 300 described with reference to FIGS. 3A and 3B, the crystal growth device 400 has a multi-part holding plate with two holding plate parts 412, 413 that are arranged on the source material 410 for growing the semiconductor 428. Thus, the holding plate parts 412, 413 are in direct contact with the source material 410. Of the holding plate parts 412, 413, one holding plate part 412 is formed as a disk and is arranged in the center of the crucible 402 on the source material 410. The other holding plate part 413 is formed as a ring so that the disk 412 can be arranged within the ring 413. When the disk 412 and the ring 413 are arranged on the source material 410, free areas 440, 442 or free spaces are formed between the disk 412 and the ring 413 through which sublimated source material 426 can flow toward the crucible lid 406.

A seed crystal 424 is arranged on the disk 412 and is arranged on a pedestal 422. The seed crystal 424 is preferably made of AlN or of SiC, and the source material 410 is preferably made of polycrystalline AlN or SiC, respectively, so that an AlN or a SiC semiconductor can be grown with the crystal growth device 400.

FIG. 4B shows the crystal growth device 400 in a longitudinal sectional view in operation at a later time during a growth of a semiconductor 428. At this time instance, the semiconductor 428 has increased in volume both in the direction perpendicular to the holding plate 412, for example in its c-direction, and in the lateral direction, in particular in the m-direction, as sublimated source material 426 is desublimated at the seed crystal 424. Since the side surfaces of the semiconductor 428 are in the gas flow of the sublimated source material 426, the material supply at the side surfaces is comparatively large. This results in comparatively large growth rates in the lateral direction, e.g., in the m-direction. Since the material supply on the surface of the semiconductor 428 facing the crucible lid 406 is comparatively lower, a growth rate in this direction, i.e. in particular in the c-direction, is also comparatively lower. In particular, a ratio of the growth rate lateral with respect to the holding plate 512 to the growth rate perpendicular with respect to the holding plate 512 may be from 0.6 to 2.0, and in particular may be 1.0 or more.

The semiconductor 428 has a region 431 formed by deposition of gaseous source material 426 on the surface facing the crucible lid 406, i.e., in particular the c surface, of the seed crystal 424. As also described with reference to FIG. 3B, a comparatively large angle of diameter increase 432 in the c-direction can be achieved. The semiconductor 428 further has lateral regions 434, 436 formed by lateral growth along the m-direction of the semiconductor 428.

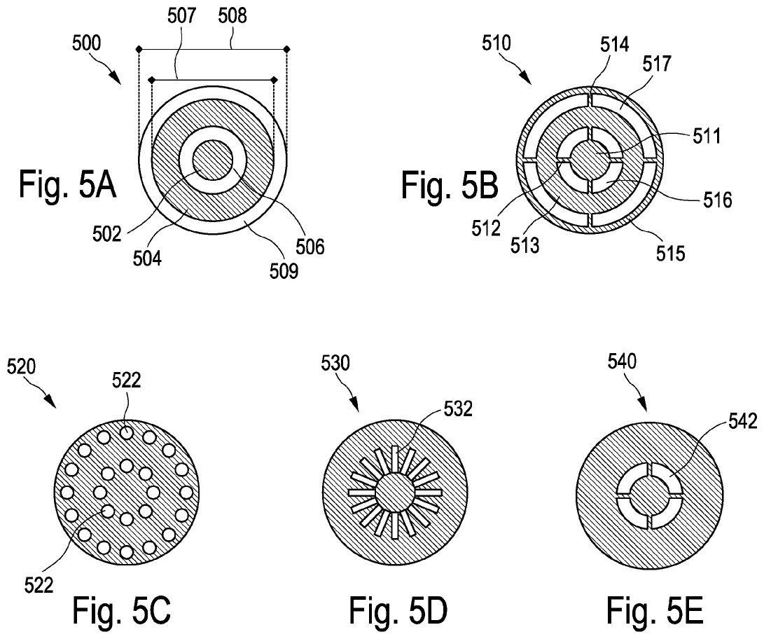

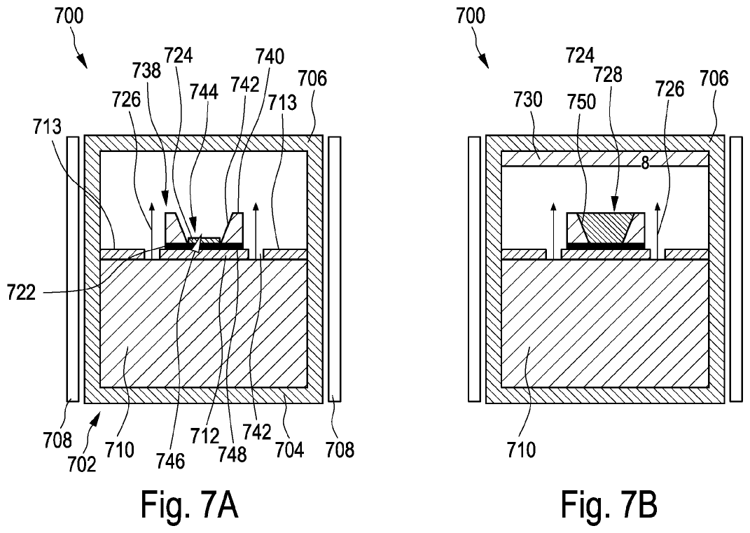

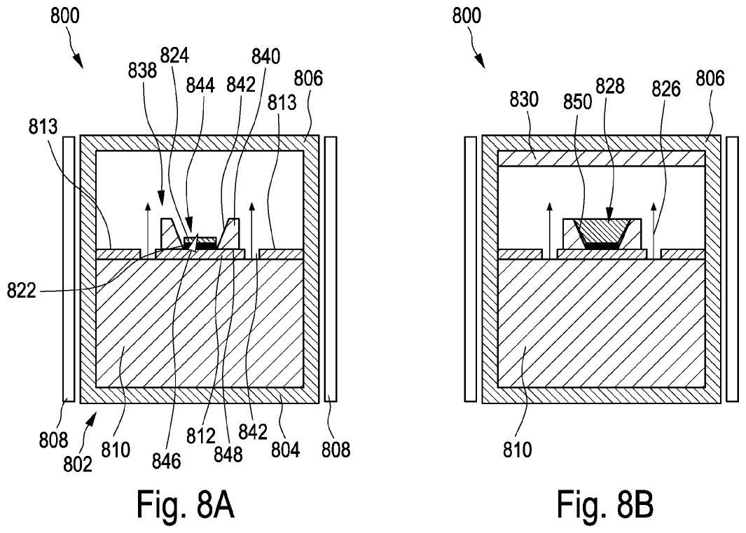

FIGS. 5A, 5B, 5C, 5D, and 5E illustrate various exemplary holding plates 500, 510, 520, 530, and 540 that may be part of a crystal growth device described herein. For example, the holding plates 500, 510, 520, 530, and 540, may be used as a holding plate of the crystal growth device 300 described with reference to FIG. 3A or 3B, or as a holding plate of the crystal growth device 400 described with reference to FIG. 4A or 4B or as a holding plate of the crystal growth device 700 described with reference to FIG. 7A or 7B or as a holding plate of the crystal growth device 800 described with reference to FIG. 8A or 8B. In addition to the geometries of the holding plates 500, 510, 520, 530, and 540 shown herein, holding plates having other geometries may also be used. The geometries shown herein are to be considered merely exemplary. However, it is preferred that a holding plate used has a free area of 5% to 75%. The free area can, for example, be formed by feedthroughs. Alternatively or additionally, the free area of 5% to 75% may also be realized by arranging a plurality of holding plate portions of a multi-part holding plate side by side on the source material when growing a semiconductor, so that free spaces are formed between the plurality of holding plate portions. Again alternatively or additionally, the free area of 5% to 75% may also be realized by the holding plate having a smaller outer diameter than the inner diameter of the crucible vessel so that gaseous source material can flow past the holding plate during growth of the semiconductor.

The two-piece holding plate 500 shown in FIG. 5A includes a disk 502 arranged within a ring 504. An open space 506 is formed between the disk 502 and the ring 504, particularly during growth of a semiconductor, through which gaseous source material can flow. In addition, the holding plate has an outer diameter 507 that is smaller than the inner diameter 508 of a crucible (not shown). This also creates regions 509 around the holding plate 500 where the source material is not covered, i.e., exposed. Gaseous source material can also flow through these regions 509 outside the holding plate 500 toward a crucible lid during growth of the semiconductor. In particular, the disk 502 and the ring 504 may be placed on a source material arranged in a crucible vessel and are then in direct contact with the source material. For example, a seed crystal may be arranged on the disk 502. Further seed crystals may also be arranged on the ring 504.

The holding plate 510 shown in FIG. 5B is formed in one piece. In particular, the holding plate 510 is formed by an inner disk 511, which is connected to a ring 513 by a plurality of inner webs 512. The ring 513 is in turn connected by outer webs 514 to an outer ring 515. The diameter of the holding plate 510 may be such that the holding plate 510 with the outer ring 515 can be placed on a rim of a crucible. Alternatively, the diameter of the holding plate 510 may be such that the holding plate 510 can be placed directly on a source material located in a crucible vessel. By being connected by inner and outer webs 512, 514, the holding plate 510 has a plurality of feedthroughs 516, 517 formed between the disk 511 and the ring 513 and between the ring 513 and the outer ring 515. For example, a seed crystal may be arranged on the inner disk 511. Additionally, further seed crystals may be arranged on the ring 513.

The free area at the holding plates 500 and 510 is between 40% and 50%. The other holding plates 520, 530, 540 are each formed in one piece and have a plurality of feedthroughs 522, 532, 542 formed such that the holding plates 520, 530, 540 each have a free area between 10% and 20%.

The feedthroughs 522 of the holding plate 520 are each circular in shape and arranged along an imaginary circle around the center of the holding plate 520. The feedthroughs 532 are rectangular in shape and point radially away from the center of the holding plate 530. The feedthroughs 542 are arcuate in shape and extend along an imaginary circle around the center of the holding plate 540. In the case of the holding plates 520, 530, and 540, a seed crystal can be arranged in the center, which is then surrounded by the feedthroughs 522, 532, 542. As a result, gaseous source material can flow through the feedthroughs 522, 532, 542 in the direction of the crucible lid and desublimate, in particular, on the side surfaces, i.e., in particular, the m-surfaces, of the seed crystal.

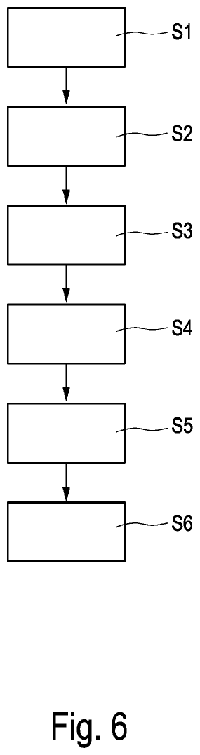

FIG. 6 shows a schematic flow diagram representing a method of growing a semiconductor.

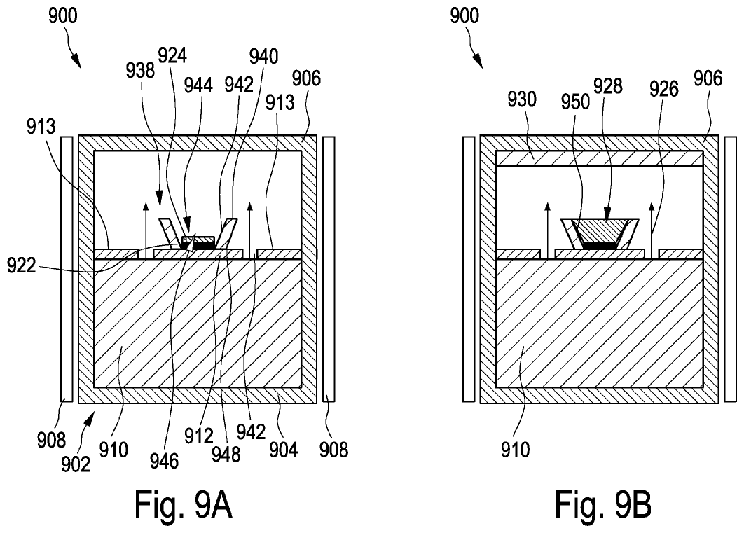

In the method, a crystal growth device is first provided (step S1), comprising a crucible, a heater, and a holding plate. The holding plate may be spaced apart from a crucible bottom of the crucible vessel for growing the semiconductor over source material arranged in the crucible vessel, such that it is located between the source material and the crucible lid. In particular, the crystal growth device used in the method may be configured as described with reference to FIGS. 3A and 3B or as described with reference to FIGS. 4A and 4B or as described with reference to FIGS. 7A and 7B or as described with reference to FIGS. 8A and 8B or as described with reference to FIGS. 9A and 9B. By way of example, the method may be carried out using the crystal growth device 300 described with reference to FIGS. 3A and 3B or using the crystal growth device 400 described with reference to FIGS. 4A and 4B or using the crystal growth device 700 described with reference to FIGS. 7A and 7B or using the crystal growth device 800 described with reference to FIGS. 8A and 8B or using the crystal growth device 900 described with reference to FIGS. 9A and 9B.

For growing the semiconductor, a source material, for example polycrystalline AlN or SiC, is introduced into the crucible vessel of the crucible (step S2). The source material is in particular in powder form and can be pressed for better insertion and heating. The holding plate is then arranged over the source material (step S3), which can be formed, for example, as described with reference to FIGS. 5A to 5E. For example, depending on the crystal growth device, the holding plate may be arranged over the source material by being arranged on a rim of the crucible, as described with reference to FIGS. 3A and 3B. Alternatively, the holding plate may be arranged over the source material by being placed directly on the source material as described with reference to FIGS. 4A and 4B and then being in direct contact with the source material. For example, multiple holding plate parts of a multi-part holding plate may also be arranged directly on the source material.

When the one-piece holding plate or the multi-piece holding plate is arranged on the source material, a seed crystal is placed on the holding plate or a holding plate part (step S4). If the source material is polycrystalline AlN or SiC, the seed crystal is also made of AlN or SiC accordingly. The crucible vessel is then covered by arranging a crucible lid on the crucible vessel (step S5). If the holding plate is arranged on the crucible rim, the crucible lid is arranged in particular on the holding plate. By arranging the crucible lid, a closed gas space is provided above the source material in which the semiconductor is grown. When the crucible lid is arranged on the crucible vessel, the holding plate is located between the source material and the crucible lid and is spaced apart from the crucible lid and the bottom of the crucible in particular. Subsequently, the source material is heated (step S6) so that the source material arranged in the crucible vessel at least partially and in particular by sublimation changes into the gas phase.

A temperature gradient is set in the crucible between a nucleation temperature of the seed crystal and a source temperature of the source material, which is from 50 K to 150 K during the growth of the semiconductor. Due to the temperature gradient, the sublimated source material flows toward the colder crucible lid, so that the source material that has changed to its gas phase can desublimate at the seed crystal. Due to the use of the holding plate, the semiconductor grows at a comparatively high growth rate in the lateral direction of the semiconductor by desublimating the source material. Thus, it can be achieved that the semiconductor reaches its target diameter with only fewer iterations of the method described herein. Furthermore, the method can be used to fabricate a semiconductor that has a comparatively high crystal quality. For example, the method can be used to fabricate a semiconductor, in particular of AlN or SiC, that has substantially no dislocations in at least 90% of its volume that have a Burgers vector with a component along the <0001>-direction, and that has a diameter of 10 mm or more in at least one direction. Further, a semiconductor fabricated by the method may have a c-lattice parameter that varies in at least 90% of the volume of the semiconductor in a range of 0.00060 Å or less, and/or have an a-lattice parameter that varies in the entire volume of the semiconductor in a range of A or less.

A semiconductor fabricated by the method can be used to produce a semiconductor substrate. For example, the semiconductor may be mechanically and/or chemically processed such that a semiconductor substrate having a diameter of at least 10 mm, e.g., 100 mm, and a thickness of from 0.1 mm to, e.g., from 0.5 mm to 3 mm is directly fabricated from the semiconductor.

The semiconductor can also be used to first produce a seed wafer, which is then used in a further crystal growth process to produce the semiconductor substrate. For example, the crystal growth device described with reference to FIGS. 1A to 1C may be used to fabricate the semiconductor substrate using the seed wafer. The seed disk would then be arranged in the crucible facing the source material, so that there is a free viewing axis between the source material and the seed disk, and sublimated source material would impinge directly on the surface of the seed crystal facing the source material, that is, in particular, on the c surface thereof. This would have the advantage that the semiconductor substrate on the seed disk would grow in particular in the direction of the source material, i.e. in particular in the c-direction in the case of a Wurtzite crystal, and the semiconductor substrate would increase in thickness comparatively faster.

FIG. 7A schematically and exemplary shows in a longitudinal sectional view, a crystal growth device 700 for growing a semiconductor according to another embodiment of the present invention in operation and at the beginning of growing the semiconductor. The crystal growth device 700 comprises the same components as the crystal growth device 400 described with reference to FIGS. 4A and 4B. Accordingly, the crystal growth device 700 includes a crucible 702. The crucible 702 also has a crucible vessel 704 and a crucible lid 706. A source material 710 is arranged in the crucible vessel 704 during operation of the crystal growth device 700. The crystal growth device 700 further comprises a heater 708, which may be formed by or include one or more induction coils. A holding plate 712, 713 is arrange directly on the source material 710. For further details and possible variations of these components, it is referred to the description of the crystal growth device 400 provided with reference to FIGS. 4A and 4B. Corresponding reference signs are used in FIGS. 7A and 7B wherein the first number of the respective reference signs used in FIGS. 4A and 4B has been changed from “4” to “7”.

In contrast to the crystal growth device 400 described with reference to FIGS. 4A and 4B, the crystal growth device 700 comprises an additional crystal growth mold 738. The crystal growth mold 738 comprises a mold body 740 having inner side walls 742 that are configured to enclose a growth volume 744 in which the semiconductor can grow. The crystal growth mold 738 is arranged on pedestal 722 that has a larger lateral diameter than a seed crystal 724 that is arranged on the pedestal 722. The mold body 740 comprises a bottom mold opening 746 that is located in a bottom side 748 of the mold body 740. The seed crystal 724 arranged on the larger diameter pedestal 722 sits inside the bottom mold opening 746 and thereby within the growth volume 744 formed by the mold body's inner side walls 742. The inner side walls 742 of the crystal growth mold 738 are inclined such that the semiconductor 728 when growing inside the growth volume 744 increases in diameter to its lateral sides. However, the diameter increase is predefined and limited by the inner side walls 742 of the mold body 740. The crystal growth mold 738 may also be used together with the crystal growth device 300 described with reference to FIGS. 3A and 3B.

FIG. 7B schematically and exemplary shows the crystal growth device 700 described with reference to FIG. 7A in a longitudinal sectional view in operation at a comparatively later time instance during growth of a semiconductor. At this time instance, the semiconductor 728 has already gained volume. In particular, due to desublimation of the gaseous source material 726, the semiconductor 728 has filled the growth volume 744 of the crystal growth mold 738. As can be seen in FIG. 7B, the lateral sides 750 of the semiconductor 728 extend along the inner side walls 742 of the mold body 740, i.e., they follow the inclination of the inner side walls 742.

FIG. 8A schematically and exemplary shows in a longitudinal sectional view, a crystal growth device 800 for growing a semiconductor 828 according to another embodiment of the present invention in operation and at the beginning of growing the semiconductor 826. The crystal growth device 800 also comprises the most of the components of the crystal growth device 400 described with reference to FIGS. 4A and 4B. Accordingly, the crystal growth device 800 also includes a crucible 802. The crucible 802 also has a crucible vessel 804 and a crucible lid 806. A source material 810 is arranged in the crucible vessel 804 during operation of the crystal growth device 800. The crystal growth device 800 further comprises a heater 808, which may be formed by or include one or more induction coils. The holding plate 812, 813 is arrange directly on the source material 810. For further details and possible variations of these components, it is referred to the description of the crystal growth device 400 provided with reference to FIGS. 4A and 4B. Corresponding reference signs are used in FIGS. 8A and 8B wherein the first number of the respective reference signs used in FIGS. 4A and 4B has been changed from “4” to “8”.

As the crystal growth device 700 described with reference to FIGS. 7A and 7B, the crystal growth device 800, too, comprises a crystal growth mold 838. The crystal growth mold 838 is configured similar to the crystal growth mold 738 of crystal growth device 700. However, in contrast to the crystal growth mold 738, the crystal growth mold 838 is configured such that the mold body 840 laterally encloses a pedestal 822. Thus, in contrast to the crystal growth device 700, in the crystal growth device 800, the crystal growth mold 838 is not arranged on a pedestal but directly on the holding plate 812.

The mold body 840 has a bottom mold opening 846 that is located in a bottom side 848 of the mold body 840. The bottom mold opening 846 is sized so that a seed crystal 824 arranged on the pedestal 822 can be arranged fully inside the bottom mold opening. Thus, in contrast to the crystal growth device 700, in the crystal growth device 800, the seed crystal 824 and the pedestal 822, both, are arranged fully within the bottom mold opening 846 of the mold body 840. Accordingly, the seed crystal 824 and the pedestal 822 are arranged within the growth volume 844 formed by the mold body's inner side walls 842. The crystal growth mold 838 may also be used together with the crystal growth device 300 described with reference to FIGS. 3A and 3B.

FIG. 8B schematically and exemplary shows the crystal growth device 800 described with reference to FIG. 8A in a longitudinal sectional view in operation at a comparatively later time instance during growth of a semiconductor. As can be seen in FIG. 8A, at this later time instance, the semiconductor 828 has gained volume due to desublimation of gaseous source material 826 on the seed crystal 824. During growth, the expansion in volume of the semiconductor 828 was limited to its lateral sides by the inclined inner side walls 842 of the mold body 840.

FIG. 9A schematically and exemplary shows in a longitudinal sectional view, a crystal growth device for growing a semiconductor according to another embodiment of the present invention in operation and at the beginning of growing the semiconductor. The crystal growth device 900 also comprises the most of the components of the crystal growth device 400 described with reference to FIGS. 4A and 4B. Accordingly, the crystal growth device 900 also includes a crucible 902. The crucible 902 also has a crucible vessel 904 and a crucible lid 906. A source material 910 is arranged in the crucible vessel 904 during operation of the crystal growth device 900. The crystal growth device 900 further comprises a heater 908, which may be formed by or include one or more induction coils. The holding plate 912, 913 is arrange directly on the source material 910. For further details and possible variations of these components, it is again referred to the description of the crystal growth device 400 provided with reference to FIGS. 4A and 4B. Corresponding reference signs are used in FIGS. 9A and 9B wherein the first number of the respective reference signs used in FIGS. 4A and 4B has been changed from “4” to “9”.

The crystal growth device 900 comprises a crystal growth mold 938. The crystal growth mold 938 is configured similar to the crystal growth mold 838 of crystal growth device 800. However, in contrast to the crystal growth mold 838, the crystal growth mold 938 has side walls with a constant lateral thickness.

As the mold body 840, also the mold body 940 has a bottom mold opening 946 that is located in a bottom side 948 of the mold body 940. The bottom mold opening 946 is sized so that a seed crystal 924 arranged on the pedestal 922 can be arranged fully inside the bottom mold opening. Accordingly, the seed crystal 924 and the pedestal 922 are arranged within the growth volume 944 formed by the mold body's inner side walls 842. The crystal growth mold 938 may also be used together with the crystal growth device 300 described with reference to FIGS. 3A and 3B.

FIG. 9B schematically and exemplary shows the crystal growth device described with reference to FIG. 9A in a longitudinal sectional view in operation at a comparatively later time instance during growth of a semiconductor. At this later time instance, the semiconductor 928 has already gained volume. In particular, due to desublimation of the gaseous source material 926, the semiconductor 928 has filled the growth volume 944 of the crystal growth mold 938. As can be seen in FIG. 9B, the lateral sides 950 of the semiconductor 928 extend along the inner side walls 942 of the mold body 940.

Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality.

Any reference signs in the claims should not be construed as limiting the scope.

### LIST OF REFERENCE SIGNS

100 crystal growth device
102 crucible
104 crucible vessel
106 crucible lid
108 source material
110 seed crystal
112 susceptor
114 thermal insulation
116 first opening
118 crucible bottom
120 second opening
122 gaseous source material
124 semiconductor
126 heater
200 unit cell
202 c surface
204 unit vector a1
206 unit vector a2
208 m surface
210 a surface
212 normal vector tom surface
300 crystal growth device
302 crucible
304 crucible vessel
306 crucible lid
308 heater
310 source material
312 holding plate
314, 316 feedthroughs
318 closed gas space
320 surface
322 pedestal
324 seed crystal
326 source material
328 semiconductor
330 semiconductor material
331 area
332 angle of diameter increase
334, 336 lateral areas
338 exterior surface
340 normal vector
400 crystal growth device
402 crucible
404 crucible vessel
406 crucible lid
410 source material
412, 413 holding plate parts (disk, ring)
422 pedestal
424 seed crystal
426 sublimated source material
428 semiconductor
431 region formed by deposition of gaseous source material
432 large angle of diameter increase
434, 436 lateral areas
440, 442 free areas
500, 510, 520, 530, 540 holding plates
502 disk
504 ring
507 outer diameter
508 inner diameter
509 regions outside the holding plate
510 holding plate
511 disk
512, 514 inner and outer webs
513 ring
515 outer ring
516, 517 feedthroughs
520, 530, 540 holding plates
522, 532, 42 feedthroughs
700 crystal growth device
702 crucible 702
704 crucible vessel
706 crucible lid
708 heater
710 source material
712, 713 holding plate
722 pedestal
724 seed crystal
726 sublimated source material
728 semiconductor
738 crystal growth mold
740 mold body
742 inner side walls
744 growth volume
746 bottom mold opening
748 bottom side
750 lateral sides of the semiconductor
800 crystal growth device
802 crucible 702
804 crucible vessel
806 crucible lid
808 heater
810 source material
812, 813 holding plate
822 pedestal
824 seed crystal
826 sublimated source material
828 semiconductor
838 crystal growth mold
840 mold body
842 inner side walls
844 growth volume
846 bottom mold opening
848 bottom side
850 lateral sides of the semiconductor
900 crystal growth device
902 crucible 702
904 crucible vessel
906 crucible lid
908 heater
910 source material
912, 913 holding plate
922 pedestal
924 seed crystal
926 sublimated source material
928 semiconductor
938 crystal growth mold
940 mold body
942 inner side walls
944 growth volume
946 bottom mold opening
948 bottom side
950 lateral sides of the semiconductor

1. A crystal growth device for growing a semiconductor from a gas phase, the crystal growth device comprising:
a crucible comprising a crucible vessel and a crucible lid arranged on the crucible vessel, the crucible vessel being configured to receive and hold a source material for the semiconductor during growth of the semiconductor,
a heater that is configured and arranged to heat the source material in the crucible vessel so that the source material at least partially changes to its gaseous phase and flows toward the crucible lid, and
a holding plate configured to hold a seed crystal on a side of the holding plate facing the crucible lid and to allow deposition of the source material that has changed to its gas phase on the seed crystal for growing the semiconductor, wherein
the at least one holding plate is further configured to be arranged at a distance from a crucible bottom of the crucible vessel for growing the semiconductor, such that it is located between the source material and the crucible lid.

2. The crystal growth device of claim 1, wherein the holding plate is formed separately from the crucible and is removable from the crucible for introduction of the source material and can be arranged between the source material and the crucible lid for growth of the semiconductor.

3. The crystal growth device of claim 1, wherein the holding plate comprises at least one feedthrough which, when the holding plate is arranged between the source material and the crucible lid, extends from the surface of the holding plate facing the source material to the surface of the holding plate facing away from the bottom of the crucible, so that the source material having changed into its gas phase can pass through the at least one feedthrough.

4. The crystal growth device of claim 1, comprising a crystal growth mold having a mold body with inner side walls that enclose a growth volume in which the semiconductor can be grown, wherein the crystal growth mold is arranged and configured such that a pedestal for holding the seed crystal can be arranged within a bottom mold opening that is located in a bottom side of the mold body.

5. The crystal growth device of claim 1, comprising a pedestal for holding the seed crystal and comprising a crystal growth mold having a mold body with inner side walls that enclose a growth volume in which the semiconductor can grow, wherein the crystal growth mold is arranged on the pedestal and has a bottom mold opening that is located in a bottom side of the mold body such that the seed crystal held by the pedestal can be arranged within the bottom mold opening for growing the semiconductor.

6. A method of growing a semiconductor from a gas phase, the method comprising the steps of:
providing a crystal growth device according to claim 1,
placing a source material for the semiconductor into the crucible vessel,
arranging the holding plate above the source material so that the holding plate is spaced from the crucible bottom of the crucible vessel,
arranging at least one seed crystal on the surface of the holding plate facing away from the source material,
arranging the crucible lid on the crucible vessel so that the holding plate is located between the source material and the crucible lid, and
heating the source material so that the source material at least partly changes into the gas phase and flows towards the crucible lid, so that the source material which has changed into its gas phase can desublimate on the seed crystal.

7. The method of claim 6, wherein a temperature difference of 50 K to 150 K between a nucleation temperature of the seed crystal and a source temperature of the source material occurs during deposition of the source material that has changed to its gaseous phase.

8. The method of claim 6, wherein during the deposition of the source material that has changed to its gas phase on the seed crystal, a ratio of an m-growth rate of the semiconductor on its m-surface and a c-growth rate of the semiconductor on its c-surface is 0.6 or more.

9. The method of claim 6, wherein arranging the holding plate over the source material comprises arranging the holding plate onto the source material during growth of the semiconductor.

10. The method of claim 6, wherein arranging the holding plate over the source material comprises arranging the holding plate on a crucible rim of the crucible vessel.

11. The method of claim 6, wherein arranging the at least one seed crystal comprises arranging the seed crystal on a pedestal on the holding plate having a thermal conductivity λ of 30 W/(m*K) or less at room temperature and/or at a growth temperature of 2000° C. at least in a direction of that surface of the pedestal on which the seed crystal is arranged.

12. A semiconductor, in particular comprising or being made of AlN or SiC, having substantially no dislocations in at least 90% of its volume that have a Burgers vector with a component along the <0001>-direction, and having a diameter of 10 mm or more in at least one direction.

13. The semiconductor of claim 12, wherein a c-lattice parameter in at least 90% of the volume of the semiconductor varies in a range of 0.00060 Å or less, and/or an a-lattice parameter in the entire volume of the semiconductor varies in a range of 0.00040 Å or less.

14. A use of the semiconductor claim 12 for the fabrication of a semiconductor substrate having substantially no dislocations in at least 90% of its volume that have a Burgers vector having a component along the <0001>-direction.

15. The use of claim 14, wherein the semiconductor substrate is fabricated by mechanically and/or chemically processing the semiconductor, or wherein fabricating the semiconductor substrate comprises first fabricating, by mechanically and/or chemically processing the semiconductor, a seed wafer that is used to fabricate the semiconductor substrate by a crystal growth method, the crystal growth method preferably comprising arranging the seed wafer opposite a source material in a crucible so that there is a free viewing axis between the seed wafer and the source material.

16. A semiconductor substrate, in particular comprising or being made of AlN or SiC, having substantially no dislocations in at least 90% of its volume that have a Burgers vector with a component along the <0001>-direction, and having a diameter of 10 mm or more in at least one direction.

17. The semiconductor substrate of claim 16, wherein an asymmetric (10-12) reflex and/or a symmetric (0002) reflex, in particular, of X-ray radiation of a copper K-alpha emission, has a full width at half maximum of 12 arcseconds or less, measured with a spot size of at least 2 mm×10 mm.
